(19) United States
(12) Patent Application Publication
(10) Pub. No.: US 2010/0258173 A1
(43) Pub. Date: Oct. 14, 2010

(54) POLISHING A THIN METALLIC SUBSTRATE FOR A SOLAR CELL

(76) Inventors: Joseph LAIA, Morgan Hill, CA (US); Paul Shufflebotham, San Jose, CA (US); Daniel R. Juliano, Santa Clara, CA (US); Robert Martinson, Palo Alto, CA (US); Timothy Kueper, Santa Clara, CA (US)

Correspondence Address: Weaver Austin Villeneuve & Sampson LLP, P.O. BOX 70250, OAKLAND, CA, 94612-0250, US

(21) Appl. No.: 12/422,620

(22) Filed: Apr. 13, 2009

(51) Int. Cl. H01L 31/00; B24B 1/00; H01L 21/304

(52) U.S. Cl. 136/256; 451/36; 451/59; 438/57; 257/E21.237

(57) ABSTRACT

A method for fabricating a solar cell. The method includes providing a thin metallic substrate in roll form. The method also includes applying an abrasive grit to a surface of the thin metallic substrate. The method includes mechanical-polishing the surface with the abrasive grit such that the surface is polished to remove at least one defect from the surface. Mechanical-polishing the surface of the thin metallic substrate is by a roll-to-roll polishing process of the surface of the thin metallic substrate. Moreover, the method includes depositing an absorber layer of the solar cell on the thin metallic substrate.

### TECHNICAL FIELD

Embodiments of the present invention relate generally to the field of photovoltaic technology.

### BACKGROUND

In the drive for renewable sources of energy, photovoltaic technology has assumed a preeminent position as a cheap renewable source of clean energy. In particular, solar cells based on the compound semiconductor copper indium gallium diselenide (CIGS) used as an absorber layer offer great promise for thin-film solar cells having high efficiency and low cost. In efforts to obtain thin-film solar cells based on CIGS with lower cost, technological development has pursued a goal of using substrates having a large areal footprint, on the order of 1 meter in width, and equal or greater length. Recently, manufacturing schemes employing in-line coating processes on substrates provided from roll sheet stock have been investigated to achieve this goal.

However, unlike the small form-factor substrates used in the past to fabricate laboratory demonstrations of thin-film solar cells, these new substrate materials present a number of engineering challenges. One such challenge is conditioning these new substrates to receive the layers deposited upon the substrates during the solar-cell fabrication process while maintaining: high yields for the process, a defect-free substrate that produces high performance, and high solar-cell efficiency, as a figure of merit.

### SUMMARY

Embodiments of the present invention include a method for fabricating a solar cell. The method includes providing a thin metallic substrate in roll form. The method also includes applying an abrasive grit to a surface of the thin metallic substrate. The method includes mechanical-polishing the surface with the abrasive grit such that the surface is polished to remove at least one defect from the surface. Mechanical-polishing the surface of the thin metallic substrate is by a roll-to-roll polishing process of the surface of the thin metallic substrate. Moreover, the method includes depositing an absorber layer of the solar cell on the thin metallic substrate.

### DESCRIPTION OF THE DRAWINGS

The accompanying drawings, which are incorporated in and form a part of this specification, illustrate embodiments of the invention and, together with the description, serve to explain the embodiments of the invention:

FIG. 1A is a cross-sectional elevation view of a layer structure of a solar cell, in accordance with an embodiment of the present invention.

FIG. 1B is a schematic diagram of a model circuit of a solar cell, electrically connected to a load, in accordance with an embodiment of the present invention.

FIG. 2A is a cross-sectional elevation view of a thin metallic substrate prior to deposition of layers in fabrication of a solar cell illustrating various types of defects at a surface of the thin metallic substrate having potentially deleterious effects on solar-cell efficiency, upon which embodiments of the present invention may be implemented.

FIG. 2B is an expanded view of a portion of the cross-sectional elevation view of FIG. 2A after depositing layers to fabricate a solar cell on the thin metallic substrate illustrating a portion of photocurrent being lost to a shunt defect associated with a defect at the surface of the thin metallic substrate, upon which embodiments of the present invention may be implemented.

FIG. 3A is a cross-sectional elevation view of a thin metallic substrate after mechanical-polishing a surface of the thin metallic substrate with an abrasive grit in a roll-to-roll polishing process which produces a plurality of scratches in the surface such that an average depth of the plurality of scratches is sufficient to remove at least one defect from the surface, in accordance with an embodiment of the present invention.

FIG. 3B is an expanded view of a portion of the cross-sectional elevation view of FIG. 3A, after mechanical-polishing the surface of the thin metallic substrate with the abrasive grit and depositing layers to fabricate a solar cell, showing the layers disposed on the surface of the thin metallic substrate with a plurality of scratches such that a scratch of the plurality of scratches in the surface of the thin metallic substrate is small enough as not to create a defect larger than a size that could cause damage to the solar cell, in accordance with an embodiment of the present invention.

FIG. 4 is an elevation view of a roll-to-roll surface polisher for mechanical-polishing the surface of the thin metallic substrate in roll form from a roll of material, in accordance with an embodiment of the present invention.

FIG. 5 is a flow chart illustrating a method for roll-to-roll polishing the surface of a thin metallic substrate for a semiconductor device, in accordance with an embodiment of the present invention.

FIG. 6 is a flow chart illustrating a method for fabricating a solar cell, in accordance with an embodiment of the present invention.

FIG. 7A is a cross-sectional elevation view of a thin metallic substrate after irradiating a surface of the thin metallic substrate with a high-intensity energy source, in accordance with an embodiment of the present invention.

FIG. 7B is an expanded view of a portion of the cross-sectional elevation view of FIG. 3A after irradiating a surface of the thin metallic substrate with a high-intensity energy source and depositing layers to fabricate a solar cell, the layers disposed on an altered surface layer of the thin metallic substrate, in accordance with an embodiment of the present invention.

FIG. 8 is an elevation view of a roll-to-roll surface smoother for smoothing the surface of the thin metallic substrate in roll form from a roll of material, in accordance with an embodiment of the present invention.

FIG. 9 is a flow chart illustrating a method for smoothing the surface of the thin metallic substrate, in accordance with an embodiment of the present invention.

FIG. 10 is a flow chart illustrating a method for fabricating a solar cell, in accordance with an embodiment of the present invention.

FIG. 11 is a flow chart illustrating a method for roll-to-roll smoothing the surface of the thin metallic substrate, in accordance with an embodiment of the present invention.

The drawings referred to in this description should not be understood as being drawn to scale except if specifically noted.

### DESCRIPTION OF EMBODIMENTS

Reference will now be made in detail to the various embodiments of the present invention. While the invention will be described in conjunction with the various embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following description of embodiments of the present invention, numerous specific details are set forth in order to provide a thorough understanding of the present invention. However, it should be appreciated that embodiments of the present invention may be practiced without these specific details. In other instances, well known methods, procedures, and components have not been described in detail as not to unnecessarily obscure embodiments of the present invention.

### Physical Description of Embodiments of the Present Invention for a Solar Cell Having a Polished Thin Metallic Substrate

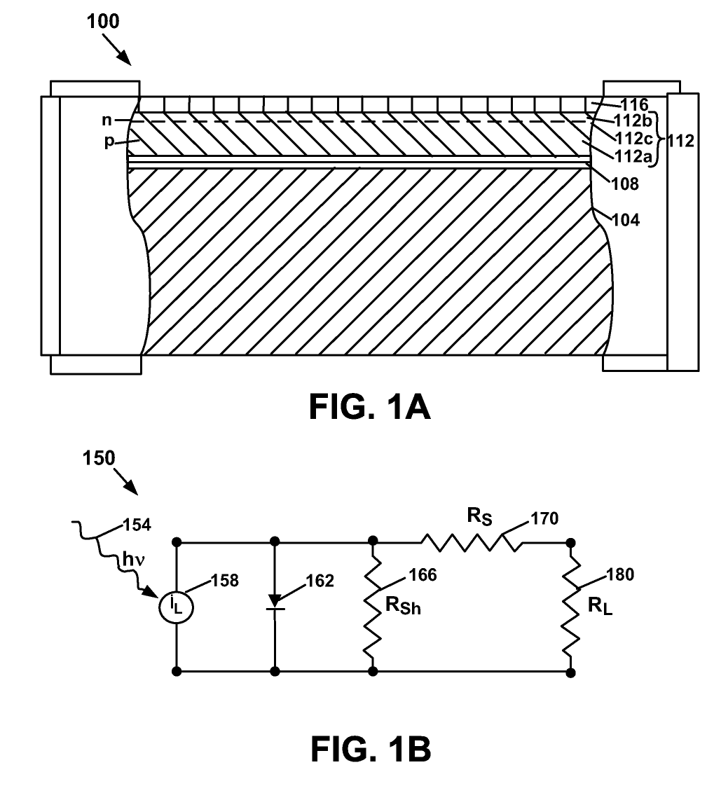

With reference to FIG. 1A, in accordance with an embodiment of the present invention, a cross-sectional elevation view of a layer structure of a solar cell 100 is shown. The solar cell 100 includes a thin metallic substrate 104. A surface of the thin metallic substrate 104 is mechanical-polished with an abrasive grit in a roll-to-roll process such that mechanical-polishing produces a surface having a plurality of scratches such that an average depth of the plurality of scratches is sufficient to remove at least one defect from the surface. As used herein, a defect on the surface of the thin metallic substrate 104 is defined as a defect capable of producing a shunt defect in a solar cell 100, or semiconductor device, that is fabricated incorporating the thin metallic substrate 104. In accordance with the embodiment of the present invention, an absorber layer 112 of the solar cell 100 is disposed on the altered surface of the thin metallic substrate 104; the absorber layer 112 may include a layer of the material copper indium gallium diselenide (CIGS) having the chemical formula Cu(In₁₋ₓGaₓ)Se₂, where x may be a decimal less than one but greater than zero that determines the relative amounts of the constituents, indium, In, and gallium, Ga. Alternatively, the absorber layer may further include a semiconductor material selected from the group consisting of CIGS, cadmium telluride (CdTe) and amorphous silicon (a-Si), without limitation thereto, as the fabrication of a solar cell from a variety of semiconductor materials is within the spirit and scope of embodiments of the present invention. The thickness of the thin metallic substrate 104 may be between less than 0.015 inches and greater than 0.0005 inches. Since it is difficult to mechanical-polish a thin metallic substrate, for example, thin metallic substrate 104, which has a thickness less than about 0.015 inches in a roll-to-roll process, embodiments of the present invention provide a means to overcome these difficulties. Moreover, a CIGS solar cell 100 having a thin metallic substrate 104 possesses considerable mechanical flexibility making it useful in a variety of applications not amenable to conventional solar cell technology, which often employs solar cells fabricated on thick stiff substrates.

As shown, the absorber layer 112 includes a p-type portion 112a and an n-type portion 112b. As a result, a pn homojunction 112c is produced in the absorber layer 112 that serves to separate charge carriers that are created by light incident on the absorber layer 112. To facilitate the efficient conversion of light energy to charge carriers in the absorber layer 112, the composition of the p-type portion 112a of the absorber layer 112 may vary with depth to produce a graded band gap of the absorber layer 112. Alternatively, the absorber layer 112 may include only a p-type CIGS material layer and a pn heterojunction may be produced between the absorber layer 112 and an n-type layer, such as cadmium sulfide, CdS, zinc sulfide, ZnS, or indium sulfide, InS, disposed on its top surface in place of the n-type portion 112b shown in FIG. 1A. However, embodiments of the present invention are not limited to pn junctions fabricated in the manner described above, but rather a generic pn junction produced either as a homojunction in a single semiconductor material, or alternatively as a heterojunction between two different semiconductor materials, is within the spirit and scope of embodiments of the present invention.

In accordance with an embodiment of the present invention, on the surface of the n-type portion 112b of the absorber layer 112, a transparent electrically conductive oxide (TCO) layer 116 is disposed, for example, to provide a means for collection of current flow from the absorber layer 112 for conduction to an external load. The TCO layer 116 may include zinc oxide, ZnO, or alternatively a doped conductive oxide, such as aluminum zinc oxide, AlₓZn₁₋ₓO_{y} and indium tin oxide, InₓSn₁₋ₓO_{y}, where the subscripts x and y indicate that the relative amount of the constituents may be varied. These TCO layer materials may be sputtered directly from an oxide target, or alternatively the TCO layer may be reactively sputtered in an oxygen atmosphere from a metallic target, such as zinc, Zn, Al—Zn alloy, or In—Sn alloy targets. For example, the zinc oxide may be deposited on the absorber layer 112 by sputtering from a zinc-oxide-containing target; alternatively, the zinc oxide may be deposited from a zinc-containing target in a reactive oxygen atmosphere in a reactive-sputtering process. The reactive-sputtering process may provide a means for doping the absorber layer 112 with an n-type dopant, such as zinc, Zn, or indium, In, to create a thin n-type portion 112b, if the partial pressure of oxygen is initially reduced during the initial stages of sputtering a metallic target, such as zinc, Zn, or indium, In, and the layer structure of the solar cell 100 is subsequently annealed to allow interdiffusion of the zinc, Zn, or indium, In, with the CIGS material of the absorber layer 112. Alternatively, sputtering a compound target, such as zinc sulfide, ZnS, indium sulfide, InS, or cadmium sulfide, CdS, may also be used to provide the n-type layer, as described above, on the p-type portion 112a of the absorber layer 112.

With further reference to FIG. 1A, in accordance with the embodiment of the present invention, a conductive backing layer 108 may be disposed between the absorber layer 112 and the surface of the thin metallic substrate 104 to provide a diffusion barrier between the absorber layer 112 and the thin metallic substrate 104. The conductive backing layer 108 may include molybdenum, Mo, or other suitable metallic layer having a low propensity for interdiffusion with the absorber layer 112 composed of CIGS material, as well as a low diffusion coefficient for constituents of the thin metallic substrate 104. Moreover, the conductive backing layer 108 may provide other functions in addition to, or independent of, the diffusion-barrier function, for example, a light-reflecting function, for example, as a light-reflecting layer, to enhance the efficiency of the solar cell, as well as other functions. The embodiments recited above for the conductive backing layer 108 should not be construed as limiting the function of the conductive backing layer 108 to only those recited, as other functions of the conductive backing layer 108 are within the spirit and scope of embodiments of the present invention, as well.

With reference now to FIG. 1B, in accordance with an embodiment of the present invention, a schematic diagram of a model circuit 150 of a solar cell that is electrically connected to a load is shown. The model circuit 150 of the solar cell includes a current source 158 that generates a photocurrent, i_{L}. The photocurrent, i_{L}, is produced when a plurality of incident photons, light particles, of which one example photon 154 with energy, hν, is shown, produce electron-hole pairs in the absorber layer 112 and these electron-hole pairs are separated by the pn homojunction 112c, or in the alternative, by a pn heterojunction as described above. It should be appreciated that the energy, hν, of each incident photon of the plurality of photons should exceed the band-gap energy, E_{g}, that separates the valence band from the conduction band of the absorber layer 112 to produce such electron-hole pairs, which result in the photocurrent, i_{L}.

The model circuit 150 of the solar cell further includes a diode 162, which corresponds to recombination currents, primarily at the pn homojunction 112c, that are shunted away from the connected load. In addition, the model circuit 150 of the solar cell includes two parasitic resistances corresponding to a shunt resistor 166 with shunt resistance, Rₛₕ, and to a series resistor 170 with series resistance, Rₛ. The solar cell may be connected to a load represented by a load resistor 180 with load resistance, R_{L}. Thus, the circuit elements of the solar cell include the current source 158, the diode 162 and the shunt resistor 166 connected across the current source 158, and the series resistor 170 connected in series with the load resistor 180 across the current source 158, as shown. As the shunt resistor 166, like the diode 162, are connected across the current source 158, these two circuit elements are associated with internal currents within the solar cell shunted away from useful application to the load. As the series resistor 170 connected in series with the load resistor 180 are connected across the current source 158, the series resistor 170 is associated with internal resistance of the solar cell that limits the current flow to the load.

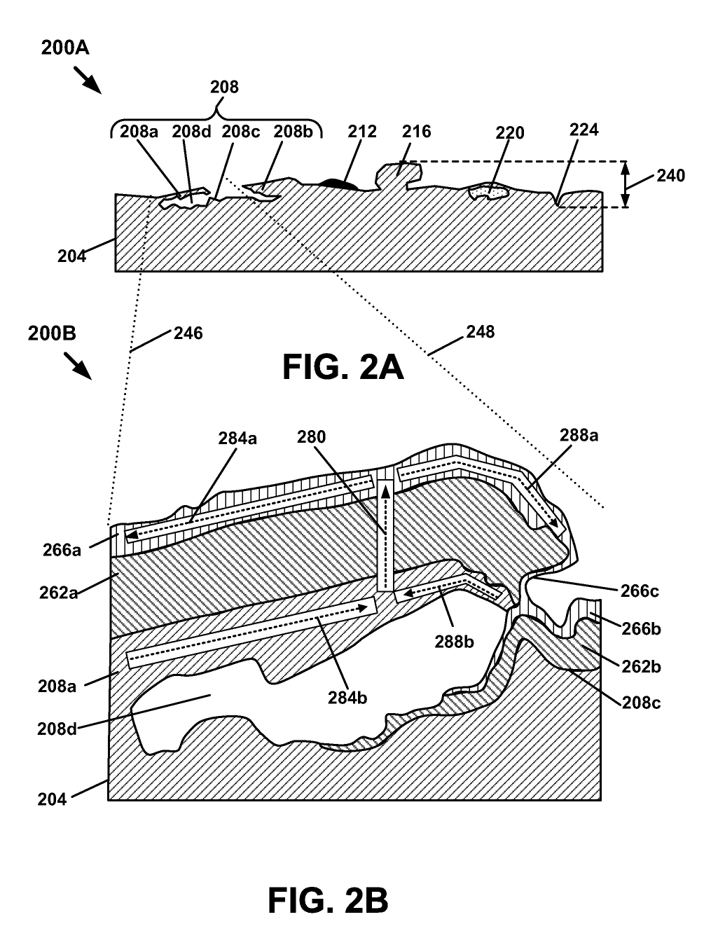

With further reference to FIG. 1B, it should be recognized that the shunt resistance may be associated with surface leakage currents that follow paths at free surfaces that cross the pn homojunction 112c; free surfaces are usually found at the edges of the solar cell along the side walls of the device that define its lateral dimensions; such free surfaces may also be found at discontinuities in the absorber layer 112 that extend past the pn homojunction 112c. The shunt resistance may also be associated with shunt defects which may be present that shunt current away from the load, as will subsequently be described in FIG. 2B. A small value of the shunt resistance, Rₛₕ, is undesirable as it lowers the open circuit voltage, V_{OC}, of the solar cell, which directly affects the efficiency of the solar cell. Moreover, it should also be recognized that the series resistance, Rₛ, is associated with: the contact resistance between the p-type portion 112a and the conductive backing layer 108, the bulk resistance of the p-type portion 112a, the bulk resistance of the n-type portion 112b, the contact resistance between the n-type portion 112b and TCO layer 116, and other components, such as conductive leads, and connections in series with the load. A large value of the series resistance, Rₛ, is undesirable as it lowers the short circuit current, I_{SC}, of the solar cell, which also directly affects the efficiency of the solar cell.

With reference now to FIG. 2A, a cross-sectional elevation view 200A of an example thin metallic substrate 204 prior to deposition of layers in fabrication of a solar cell is shown that illustrates various types of defects at a surface of example thin metallic substrate 204 having potentially deleterious effects on solar-cell efficiency. In an embodiment of the present invention, example thin metallic substrate 204 has numerous types of defects on its surface in the as-received state, which should be removed prior to deposition of layers in fabrication of the solar cell 100. For example, a thin metallic substrate 204, such as provided in the form of stainless steel foil as normally produced by steel mills, often has surface defects that make it unsuitable for use as a thin metallic substrate 204 for thin-film solar cell manufacturing without additional processing to remove these defects. However, such processing may result in a surface treatment and surface finish having non-uniformities, especially if there is a foreign material or a second phase inclusion covering part of the surface. Therefore, certain types of defects are expected to remain on the thin metallic substrate 204 and cause defective regions in the final product. Examples of the types of defects at a surface of example thin metallic substrate 204 include, without limitation: pit 208, carbonaceous residue 212, protrusion 216, inclusion 220, and rolling groove 224. For example, pit 208 may include a left over-hanging portion 208a and a right over-hanging portion 208b, which may result from metallic flakes and protrusions being rolled onto the surface of example thin metallic substrate 204 during a rolling operation for reduction from billet stock down to rolled sheet stock. Pit 208 may further include a recessed portion 208c, which forms a bottom to pit 208, and a cavity portion 208d enveloped by the left and right over-hanging portions 208a and 208b, and recessed portion 208c. Carbonaceous residue 212 may originate from oil used to lubricate the roll bearings, or adventitious sources of contamination of the rolled sheet, during the rolling operation. Protrusion 216 may be generated by material extruded from the interior of the billet during the rolling operation. Inclusion 220 may be generated by surface oxides rolled under the surface of example thin metallic substrate 204 during the rolling operation. These oxides may originate from the oxidized layers, so called “scale,” a metallurgical term of art, that are natively present on the surface of billets, or may originate from foreign oxide particles such as alumina, silicates and alumina silicates that have an adventitious origin, which, during the rolling operation, are rolled under the surface of billets, which are used to produce the rolled sheet stock of example thin metallic substrate 204. Rolling groove 224 may be generated by direct interaction of the surface of the billet with the surface of the roll during the rolling operation in reducing the billet down to rolled sheet stock.

With reference now to FIG. 2B, an expanded view 200B of a portion of the cross-sectional elevation view 200A of FIG. 2A is shown as indicated by lines of projection 246 and 248. FIG. 2B illustrates a shunt portion 288a of photocurrent 280 being lost through a shunt defect associated with a defect, pit 208, at the surface of example thin metallic substrate 204 after layers have been deposited on example thin metallic substrate 204 to fabricate a solar cell. As used herein, a defect on the surface of the thin metallic substrate 204 is defined as a defect capable of producing a shunt defect in a solar cell, or semiconductor device, that is fabricated incorporating the thin metallic substrate 204. To simplify the discussion, FIG. 2B shows the solar cell structure more generically without a conductive backing layer, as may be the case, for example, in an embodiment of the present invention. A discontinuous absorber layer is shown in two portions: portion 262a disposed on the left over-hanging portion 208a of pit 208; and, portion 262b disposed on the recessed portion 208c of pit 208, which forms the bottom of the pit. The cavity portion 208d of the pit 208 is shown partially filled with material from the deposited layers of the solar cell structure. On portions 262a and 262b of the discontinuous absorber layer are disposed, respectively, three portions of an anomalous TCO layer: portion 266a disposed on portion 262a over the left of pit 208; portion 266b disposed on portion 262b at the bottom, recessed portion 208c, of pit 208; and, portion 266c disposed on a side-wall of portion 262a of the discontinuous absorber layer located at a discontinuity associated with the pit. The shunt defect is composed of a complex of the following structures: portion 266c of the anomalous TCO layer that bridges between the portion 266a and the top of portion 266b that makes electrical contact with the portion of the substrate shown as the bottom of the left over-hanging portion 208a of pit 208. As shown, the shunt defect provides a low-resistance current path between the example thin metallic substrate 204 and portion 266a of the anomalous TCO layer.

With further reference to FIG. 2B, a representative portion of the photocurrent 280 generated in the portion 262a of the discontinuous absorber layer is shown passing from the left over-hanging portion 208a of the pit to the portion 266a of the anomalous TCO layer. The photocurrent 280 divides into two separate portions: a load portion 284a, which passes to the left through the portion 266a of the anomalous TCO layer; and the shunt portion 288a, which passes to the right through the portions 266a and 266c of the anomalous TCO layer. The load portion 284a of the photocurrent 280 corresponds to a current flowing in circuit loop containing the load resistor 180 with load resistance, R_{L}, of FIG. 1B, described above, and completes the circuit through return load current 284b, which passes to the right through a portion of the example thin metallic substrate 204 shown as the left over-hanging portion 208a of pit 208. The shunt portion 288a of the photocurrent 280 corresponds to a current flowing in a circuit loop containing the shunt resistor 166 with shunt resistance, Rₛₕ, of FIG. 1B, and completes the circuit through return shunt current 288b, which passes to the left from the shunt defect found at the discontinuity in portion 262a of the discontinuous absorber layer adjacent to entrance to the cavity portion 208d of the pit 208. Such shunt defects short circuit current that would otherwise pass to the load, which leads to loss of solar cell efficiency, and generate hot spots that can eventually lead to catastrophic shorts that break down the pn junction of the solar cell. Therefore, it is desirable to have some means for eliminating various types of defects at the surface of example thin metallic substrate 204 prior to deposition of layers in the fabrication of the solar cell.

Notwithstanding the problems attending the use of thin metallic substrates, such as example thin metallic substrate 204, it should be recognized that it is desirable to use such rolled sheet stock because of its low cost. However, removal of the defects at the surface of example thin metallic substrate 204 should be provided to preclude the costs attending yield losses of solar-cell production associated with these defects. As used herein, a thin metallic substrate 204 may include low-cost, rolled sheet stock such as stainless steel, steel, aluminum, titanium, alloys of aluminum or titanium, any metallic foil, and alternatively including a thin metallized non-metallic substrate. Examples of aluminum and titanium alloys include aluminum-silicon alloy and titanium-aluminum alloy, respectively; an example of a thin metallized non-metallic substrate is a flexible, non-conductive substrate, such as a polymer substrate, with a sputtered metallic layer; and an example of a stainless steel is 430-alloy stainless steel. The defective surface region may include a peak-to-valley roughness 240 of about 5 micrometers (μm), as shown in FIG. 2A. Therefore, in accordance with an embodiment of the present invention, it is desirable to have some means for treating example thin metallic substrate 204 to remove at least one defect up to about 5 μm below the surface of example thin metallic substrate 204.

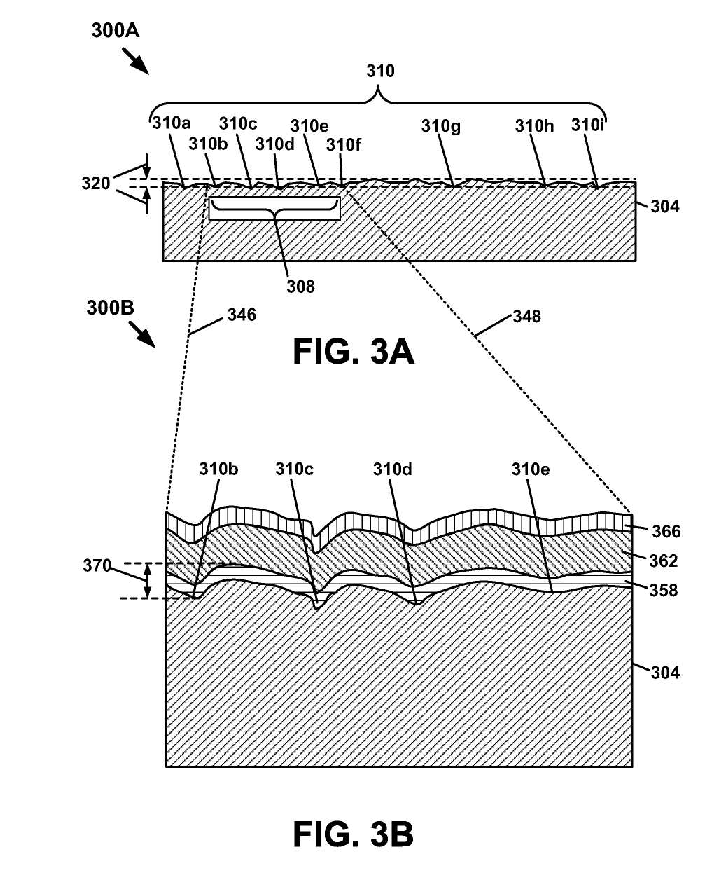

With reference now to FIG. 3A, in accordance with an embodiment of the present invention, a cross-sectional elevation view 300A of a thin metallic substrate 304 after mechanical-polishing a surface of the thin metallic substrate 304 with an abrasive grit in a roll-to-roll polishing process is shown. The surface of the thin metallic substrate 304 is mechanical-polished with the abrasive grit in a roll-to-roll process, by which the surface acquires a plurality of scratches 310 such that an average depth 320 of the plurality of scratches 310 is sufficient to remove at least one defect from the surface. The plurality of scratches 310 may include, for example, scratches 310a through 310i, such that a scratch, for example, scratch 310b, in the surface of the thin metallic substrate 304 is small enough as not to create a defect, for example, a shunt defect, larger than a size that could cause damage to the solar cell, for example, solar cell 100. In one embodiment, the thin metallic substrate 304 may include a material composed of stainless steel, without limitation thereto, as discussed above in the description of FIG. 2B. In addition, the thin metallic substrate 304 is provided in roll form for roll-to-roll polishing the surface of a thin metallic substrate 304. The roll-to-roll polishing includes the application of the abrasive grit to a surface of the thin metallic substrate 304 and mechanical-polishing the surface of the thin metallic substrate 304 with the abrasive grit, for example, with soft, compliant polishing-surfaces, such that the surface is polished to remove at least one defect from the surface. The application of the abrasive grit to the surface of the thin metallic substrate 304 may include the application of a polishing compound, which includes the abrasive grit as a constituent, to the surface of the thin metallic substrate 304. Alternatively, the application of the abrasive grit to the surface of the thin metallic substrate 304 may include the application of a flap brush, to which the abrasive grit is bound, to the surface of the thin metallic substrate 304. Moreover, the application of the abrasive grit to the surface of the thin metallic substrate 304 may include the combination of both the application of a flap brush, to which the abrasive grit is bound, and the application of a polishing compound, which includes the abrasive grit as a constituent, to the surface of the thin metallic substrate 304. Additionally, the surface of the thin metallic substrate 304 may be laser smoothed in a supplementary process such that the thin metallic substrate 304 acquires an altered surface layer as a result of the laser smoothing, as will be subsequently described. Embodiments of the present invention encompass laser smoothing that may be performed, either before, or after mechanical-polishing, both before and after mechanical-polishing, or not at all.

With further reference to FIG. 3A, in accordance with the embodiment of the present invention, a portion 308 of the thin metallic substrate 304 corresponding to the pit 208 of FIG. 2A is shown after mechanical-polishing the surface of the thin metallic substrate 304 with the abrasive grit. The cavity portion 208d of the pit 208 is removed leaving a surface topography suitable for further fabrication of a semiconductor device, such as a solar cell. The other defects: the carbonaceous residue 212, the protrusion 216, the inclusion 220, and the rolling groove 224, have been removed from the surface of the thin metallic substrate 304 having been polished away from the surface of the thin metallic substrate 304. The roughness of the surface after mechanical-polishing the thin metallic substrate 304 with the abrasive grit is substantially less than the peak-to-valley roughness 240, given by distance between the top of the protrusion 216 and the bottom of the rolling groove 224 shown in FIG. 2A, before mechanical-polishing the thin metallic substrate 304. After the thin metallic substrate 304 is mechanical-polished with the abrasive grit, the thin metallic substrate 304 is suitable for further fabrication of a semiconductor device as embodiments of the present invention are not limited to the processing of a thin metallic substrate exclusively for the fabrication of a solar cell. In particular, the surface of the thin metallic substrate 304 may be configured to receive at least one layer in the fabrication process of the semiconductor device. However, the semiconductor device may include, for example, a solar cell, such as solar cell 100. In the case that the semiconductor device is a solar cell, an absorber layer 362 of the solar cell may be disposed on the thin metallic substrate 304, as shown in FIG. 3B. The absorber layer 362 may include a layer of CIGS material. Alternatively, the absorber layer 362 may further include a semiconductor material selected from the group consisting of CIGS, CdTe and a-Si, without limitation thereto, as the fabrication of a solar cell from a variety of semiconductor materials is within the spirit and scope of embodiments of the present invention.

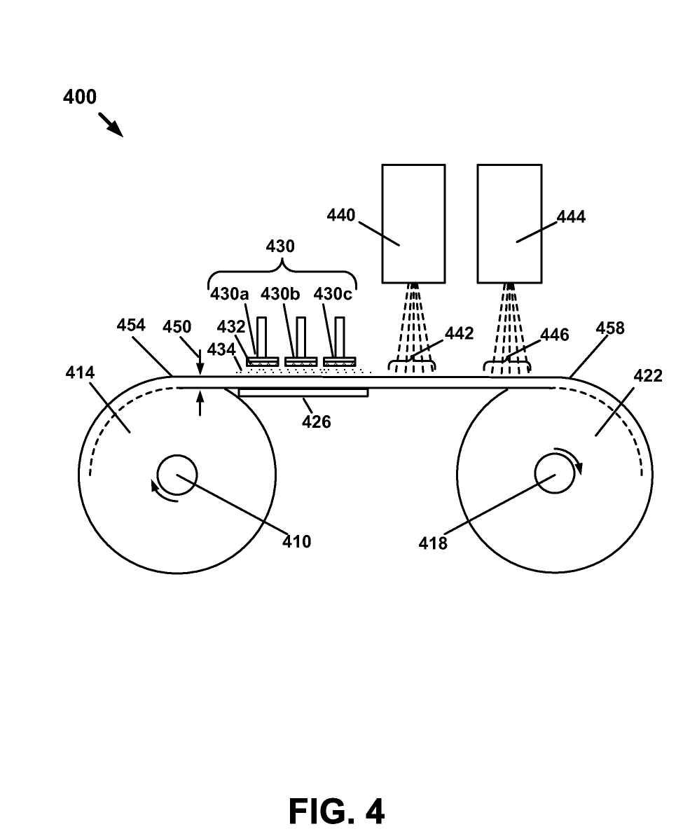

With reference now to FIG. 3B, an expanded view 300B of a portion of the cross-sectional elevation view 300A of FIG. 3A is shown as indicated by lines of projection 346 and 348. In accordance with an embodiment of the present invention, a cross-sectional elevation view of a layer structure of a solar cell is shown as it would appear after mechanical-polishing the surface of the thin metallic substrate 304 with the abrasive grit and depositing layers to fabricate the solar cell with the layers disposed on the surface of the thin metallic substrate 304. The solar cell includes the thin metallic substrate 304 with the surface of the thin metallic substrate 304 mechanical-polished with the abrasive grit to remove at least one defect from the surface. The absorber layer 362 of the solar cell may include CIGS. Alternatively, the absorber layer 362 may further include a semiconductor material selected from the group consisting of CIGS, CdTe and a-Si, without limitation thereto, as the fabrication of a solar cell from a variety of semiconductor materials is within the spirit and scope of embodiments of the present invention. A conductive backing layer 358 may be disposed between the absorber layer 362 and the surface of the thin metallic substrate 304. On the surface of the absorber layer 362, a TCO layer 366 is disposed. As shown in the expanded view of FIG. 3B, the location corresponding to the cavity portion 208d of the pit 208 has a polished surface topography. Therefore, the shunt defect associated with the defect, pit 208, shown in FIG. 2A, is absent, as well as other shunt defects, so that the number of shunt defects and density of shunt defects is reduced. In addition, the thickness of material removed by the mechanical-polishing is sufficient to remove at least one defect within 5 μm of the top of the original surface of the thin metallic substrate 304. Moreover, the mechanical-polishing of the surface of the thin metallic substrate 304, utilizes an abrasive grit that produces a plurality of scratches 310 with the abrasive grit having a grit size such that the average depth 320 of the plurality of scratches 310 is large enough for efficient removal of material from the thin metallic substrate 304, but a depth 370 of a scratch 310b of the plurality of scratches 310 is small enough as not to create a defect larger than a size that could cause damage to the semiconductor device, for example, solar cell 100. The depth 370 of the scratch 310b produced by the grit size may be less than about 5 μm, so as not to create a defect larger than the size that could cause damage to the semiconductor device, for example, solar cell 100. The grit size may be less than about 50 μm; alternatively, the grit size may be between about 1 μm and about 10 μm, without limitation thereto. Thus, an abrasive grit is used having a grit size such that the mechanical-polishing may be completed in a single mechanical-polishing that occurs on a single pass through the mechanical-polishing module 430 as next described in the discussion of FIG. 4. Alternatively, at least a second mechanical-polishing may be applied to the thin metallic substrate 304 on passing through a second of a plurality of mechanical-polishing modules of a roll-to-roll surface polisher, similar to the mechanical-polishing module 430 of the roll-to-roll surface polisher 400, such that the surface is polished to remove at least one defect from the surface of the thin metallic substrate 304.

With reference now to FIG. 4, in accordance with an embodiment of the present invention, an elevation view of a roll-to-roll surface polisher 400 for mechanical-polishing the surface of thin metallic substrate in roll form is shown. The substrate is provided to roll-to-roll surface polisher 400 in roll form from a roll of material 414. The roll-to-roll surface polisher 400 includes an unwinding spool 410 upon which the roll of material 414 including the thin metallic substrate in roll form is mounted. As shown, a portion of the roll of material 414 is unwound; the unwound portion of the roll of material 414 passes to the right and is taken up on a take-up spool 418 upon which it is rewound as a polished roll of material 422 after the thin metallic substrate has been mechanical-polished with an abrasive grit. The unwinding spool 410 and the take-up spool 418 are arranged to apply a tension to the “web,” a term of art for the unwound portion of the roll of material 414, as the web passes through the roll-to-roll surface polisher 400. The arrows adjacent to the unwinding spool 410, and the take-up spool 418 indicate that these are configured as rotating components of the roll-to-roll surface polisher 400; the unwinding spool 410 and the take-up spool 418 are shown rotating in clockwise direction, as indicated by the arrow-heads on the respective arrows adjacent to these components, to transport the unwound portion of the roll of material 414 from the unwinding spool 410 on the left to the take-up spool 418 on the right.

With further reference to FIG. 4, in accordance with an embodiment of the present invention, the roll of material 414 provides the thin metallic substrate as a sheet having a width (not shown), which may be as great as about 1 meter (m), and a thickness 450, less than about 0.015 inches. The existing art of mechanical-polishing is typically limited, for example, to steel sheet which is 0.015 inches or thicker due to the destructive mechanical forces which may be inadvertently exerted on thinner sheet. Embodiments of the present invention control the mechanical force transferred to the web by careful engineering of the polishing pad modulus, geometry, and motion, as well as the support provided beneath the web during polishing. As provided the untreated surface 454 of the roll of material 414 passes under a mechanical-polishing module 430 on the way to the take-up spool 418. The mechanical-polishing module 430 includes a plurality of polishing heads 430a, 430b and 430c and a source (not shown) from which a polishing compound 434, which includes the abrasive grit as a constituent, is dispersed to mechanical-polish the untreated surface 454 of the roll of material 414, such as shown in FIGS. 2A and 2B, producing a polished surface 458, such as shown in FIGS. 3A and 3B, on the thin metallic substrate. Alternatively, the mechanical-polishing module 430 may include a plurality of polishing heads 430a, 430b and 430c, which may include flap brushes, to which the abrasive grit is bound, to mechanical-polish the untreated surface 454 of the roll of material 414. The surface is polished to remove at least one defect from the surface. The abrasive grit may include abrasive grit selected from the group consisting of silica, (SiO₂) and alumina (Al₂O₃) particles, without limitation thereto, as is subsequently described in greater detail. In one embodiment of the present invention, the polishing compound 434 may be disposed between soft compliant polishing surfaces attached to each polishing head of the plurality of polishing heads 430a, 430b and 430c, for example, the soft compliant polishing surface of polishing pad 432 attached to polishing head 430a, and the surface of the unwound portion of the roll of material 414. As the thin metallic substrate also has a width, the plurality of polishing heads 430a, 430b and 430c are also arranged to polish in the width direction, perpendicular to the direction of transport (not shown), to mechanical-polish the full surface of the thin metallic substrate.

With further reference to FIG. 4, in accordance with an embodiment of the present invention, to demonstrate the effect of the polishing heads 430a, 430b and 430c, a hand-held, electric powered rotating polishing tool, as is commonly employed for waxing or buffing a car, was used. By applying a downward force in the range of approximately 1 pounds per square inch (psi) up to 10 psi, the surface of the substrate was mechanical-polished to remove at least one defect of a plurality of defects and to impart a pattern of scratches in a plurality of scratches having a shallow depth, for example, as for a depth of a scratch of the plurality of scratches that would be small enough as not to create a defect larger than a size that could cause damage to the solar cell. Either one of the following two polishing compounds, which are designed to remove scratches produced by 1200 grit, or finer grit, were used: 3M Perfect-It™ Paste Rubbing Compound, Part No. 06198; or alternatively, 3M Perfect-It™ 3000 Extra Cut Rubbing Compound, Part No. 6060. The ingredients of 3M Perfect-It™ Paste Rubbing Compound, Part No. 06198, are given in the following Table.

3M Perfect-It ™ Paste Rubbing Compound, Part No. 06198

| Ingredient | CASNR* | % by Weight |
|---|---|---|
| Water | 7732-18-5* | 40-70 |
| Aluminum Oxide | 1344-28-1* | 10-30 |
| Kerosene | 8008-20-6* | 10-30 |
| Castor Oil | 8001-79-4* | 1-5 |
| Poloxamine | mixture | 0.1-2.0 |
| White Mineral Oil (Petroleum) | 8042-47-5* | 0.5-1.0 |
| Naphthalene | 91-20-3* | < or = 0.08 |

*CASRN: CAS Registry Number is a Registered Trademark of the American Chemical Society.

The ingredients of 3M Perfect-It™ Paste Rubbing Compound, Part No. 6060, are given in the following Table.

3M Perfect-It ™ 3000 Extra Cut Rubbing Compound, Part No. 6060

| | | % |
|---|---|---|
| Ingredient | CASNR* | by Weight |
| Water | 7732-18-5* | 40-70 |
| Aluminum Oxide | 1344-28-1* | 10-30 |
| Hydrotreated Light Petroleum | 64742-47-8* | 5-10 |
| Distillates | | |
| Decamethylcyclopentasiloxane | 541-02-6* | 3-7 |
| Glycerin | 56-81-5* | 1-5 |
| Hydrotreated heavy naphtha | 64742-48-9* | 1-5 |
| petroleum | | |
| Dodecamethylcyclohexasiloxane | 540-97-6* | 1-5 |
| Poloxamine | Trade Secret | 0.1-2.0 |
| Solvent-Refined Heavy Paraffinic | 64741-88-4* | 0.5-1.5 |
| Petroleum Distillates | | |
| Distillates, Petroleum, Solvent- | 64741-89-5* | 0-0.5 |
| Refined Light Paraffinic | | |

*CASRN: CAS Registry Number is a Registered Trademark of the American Chemical Society.

These formulations of the polishing compounds indicate that a polishing compound used in mechanical-polishing for embodiments of the present invention may include an abrasive grit, such as aluminum oxide, also known by the term of art “alumina,” water and organic compounds, such as amongst those listed in the preceding tables.

With further reference to FIG. 4, in accordance with an embodiment of the present invention, to demonstrate the effect of the polishing heads 430a, 430b and 430c, flap brushes were used. Mechanical-polishing using flap brushes with a polishing compound having a grit size of ranging from 1 μm up to as high as 50 μm removed at least one defect of a plurality of defects. Better results were found when using a polishing compound having a grit size ranging from 1 to 10 μm. Various pressures were applied to the thin metallic substrate, for example, similar to thin metallic substrate 304, with the flap brushes designated by “high pressure,” medium pressure” and “low pressure”: high pressure being approximately 10 psi; medium pressure being 1 to 2 psi; and, low pressure being less than about 1 psi. A range for using the flap brushes from 1 to 10 psi produced a plurality of scratches such that an average depth of the plurality of scratches was large enough for efficient removal of material from the thin metallic substrate, in particular, for removing at least one defect of a plurality of defects, but such that a depth of a scratch of the plurality of scratches was small enough as not to create a defect larger than a size that could cause damage to solar-cell layers subsequently fabricated on the thin metallic substrate. Microscopic examination of the surface of thin metallic substrates, for example, similar to thin metallic substrate 304, indicated that a depth of a scratch of the plurality of scratches produced by mechanical-polishing using flap brushes was less than about 1 μm.

With further reference to FIG. 4, in accordance with an alternative, prophetic embodiment of the present invention, flap brushes may be used with an abrasive grit bound to the flap brushes. The flap brushes with bound abrasive grit may be used in either a dry or a wet process. Mechanical-polishing using flap brushes with bound abrasive grit having a grit size of ranging from 1 μm up to as high as 50 μm is expected to remove at least one defect of a plurality of defects. Better results are expected when using an bound abrasive grit having a grit size ranging from 1 to 10 μm. Various pressures may be applied to the thin metallic substrate, for example, similar to thin metallic substrate 304, with the flap brushes, to which the abrasive grit is bound, designated by “high pressure,” medium pressure” and “low pressure”: high pressure being approximately 10 psi; medium pressure being 1 to 2 psi; and, low pressure being less than about 1 psi. A range for using the flap brushes with bound abrasive grit from 1 to 10 psi is expected to produce a plurality of scratches such that an average depth of the plurality of scratches may be large enough for efficient removal of material from the thin metallic substrate, in particular, for removing at least one defect of a plurality of defects, but such that a depth of a scratch of the plurality of scratches may be small enough as not to create a defect larger than a size that could cause damage to solar-cell layers subsequently fabricated on the thin metallic substrate. Microscopic examination of the surface of thin metallic substrates, for example, similar to thin metallic substrate 304, is expected to show that a depth of a scratch of the plurality of scratches produced by mechanical-polishing using flap brushes, to which the abrasive grit is bound, is less than about 1 μm.

With further reference to FIG. 4, in accordance with an embodiment of the present invention, the mechanical-polishing may be performed such that soft compliant polishing surfaces and local symmetry of lateral forces are employed to ensure that the web, for example, the thin metallic substrate, is not subjected to a large shear force which may wrinkle, shred, or misalign the web. The mechanical-polishing may be performed such that the shear force is no larger than produced by a flap brush applying a pressure of about 10 psi. In addition, the mechanical-polishing may be performed with a flap brush applying a pressure less than about 2 psi. Moreover, a low friction backside support 426, such as a Teflon support, or an air bearing surface (ABS), may be used to minimize shear forces. Thus, the mechanical-polishing is performed such that no shear-induced damage, for example, such as wrinkling or shredding, of the thin metallic substrate occurs. The mechanical-polishing is performed such that shear deformation, which in the extreme produces shear-induced damage, is no larger than produced by a flap brush applying a pressure of about 10 psi to said thin metallic substrate having a thickness of between less than 0.015 inches and greater than about 0.0005 inches. The polishing compound 434, similar in formulation to the polishing compounds discussed above, 3M Perfect-It™ Paste Rubbing Compound, Part No. 06198, or alternatively, 3M Perfect-It™ 3000 Extra Cut Rubbing Compound, Part No. 6060, which contains an abrasive grit, may be applied continuously in the form of a liquid flowing through pores or openings in the polishing pads of the polishing heads, for example, polishing pad 432 attached to polishing head 430a. Alternatively, flap brushes, to which the abrasive grit is bound, may be used. The pressure applied to the web by the polishing head, and/or flap brush, in the contact area with the polishing head, and/or flap brush, are controlled such that all areas of the web experience the same amount of polishing activity for a given web travel speed through the mechanical-polishing module 430. Embodiments of the present invention facilitate the removal of high points on the surface of the thin metallic substrate in an efficient mechanical process which minimizes transport time of the web through the roll-to-roll polisher and the overall cost of thin metallic substrate preparation. Embodiments of the present invention also reduce chemical waste which is often associated with other surface modification techniques, for example, electropolishing, because an abrasive grit, which may be a constituent of a polishing compound or bound to a flap brush, is used in the process. Moreover, embodiments of the present invention reduce the processing time and the cost of capital equipment associated with many cleaning and electropolishing processes that are unsuitable for use in a roll-to-roll process due to their poor efficiency.

With further reference to FIG. 4, in accordance with an embodiment of the present invention, because the existing art of mechanical-polishing is typically dependent upon multiple stages of polishing with finer scales of abrasive grit, necessitating careful rinsing in between, embodiments of the present invention utilize an optimized grit size of the abrasive grit for a given solar cell application, which allows the process to be completed in a single mechanical-polishing but leaves behind a plurality of scratches, for example, plurality 310 of scratches 310a-310i. The single mechanical-polishing occurs on a single pass through the mechanical-polishing module 430, without limitation thereto. Alternatively, at least a second mechanical-polishing may be applied to the thin metallic substrate, for example, thin metallic substrate 304, on passing through a second of a plurality of mechanical-polishing modules of a roll-to-roll surface polisher, similar to the mechanical-polishing module 430 of the roll-to-roll surface polisher 400, such that the surface is polished to remove at least one defect from the surface of the thin metallic substrate. The plurality of scratches are large enough for efficient substrate removal but smaller than the known defect size for particular thin-film solar cell materials. The depth of the scratch produced by the grit size may be less than about 5 μm, so as not to create a defect larger than the size that could cause damage to the solar cell, for example, solar cell 100. Moreover, the grit size may be less than about 50 μm; alternatively, the grit size may be between about 1 μm and about 10 μm, without limitation thereto. Because of the limitations associated with the existing methods for mechanical-polishing, mechanical-polishing is typically not used for preparing thin metallic substrates, for example, a thin foil, for solar cell manufacturing. Embodiments of the present invention allow mechanical-polishing to be used in preparing thin metallic substrates that can be utilized in the fabrication of solar cells. Moreover, because of the limitations associated with existing methods for mechanical-polishing, mechanical-polishing is not normally used on roll-to-roll processing lines for thin metallic substrates thinner than about 0.015 inches. Embodiments of the present invention allow processing of thin metallic substrates as thin as about 0.0005 inches on a roll-to-roll processing line.

With further reference to FIG. 4, in accordance with an embodiment of the present invention, removal of the abrasive grit from the surface of the thin metallic substrate after mechanical-polishing the surface is provided by a rinsing module 440, which rinses the surface of the thin metallic substrate with a fluid 442, which may include, without limitation thereto, de-ionized water, to remove the abrasive grit from the surface. After rinsing the surface of the thin metallic substrate, the web passes through a drying module 444, which dries the surface with a drying gas 446, which may include, without limitation thereto, dry nitrogen or dry compressed air, after the abrasive grit has been removed from the surface. In one embodiment of the present invention, the roll-to-roll polisher may be provided with a laser smoothing module (not shown), which laser smoothes the thin metallic substrate, which is subsequently described. In embodiments of the present invention, the laser smoothing may be performed, either before, or after mechanical-polishing, both before and after mechanical-polishing, or not at all.

With further reference to FIG. 4, in accordance with an embodiment of the present invention, after the surface has been mechanical-polished with the abrasive grit, the surface is configured to receive at least one layer in a fabrication process of a semiconductor device, for example, as described above in FIG. 3B. In accordance with an embodiment of the present invention, the substrate may be selected from a group including a thin metallic substrate and a thin metallized substrate, for example, a thin metallized non-metallic substrate including a flexible, non-conductive substrate, such as a polymer substrate, with a sputtered metallic layer. In addition, the semiconductor device may include a solar cell having absorber layer 362 made of, for example, CIGS material. Alternatively, the absorber layer 362 may further include a semiconductor material selected from the group consisting of CIGS, CdTe and a-Si, without limitation thereto, as the fabrication of a solar cell from a variety of semiconductor materials is within the spirit and scope of embodiments of the present invention.

### Description of Embodiments of the Present Invention for a Method of Roll-to-Roll Polishing a Thin Metallic Substrate for a Solar Cell

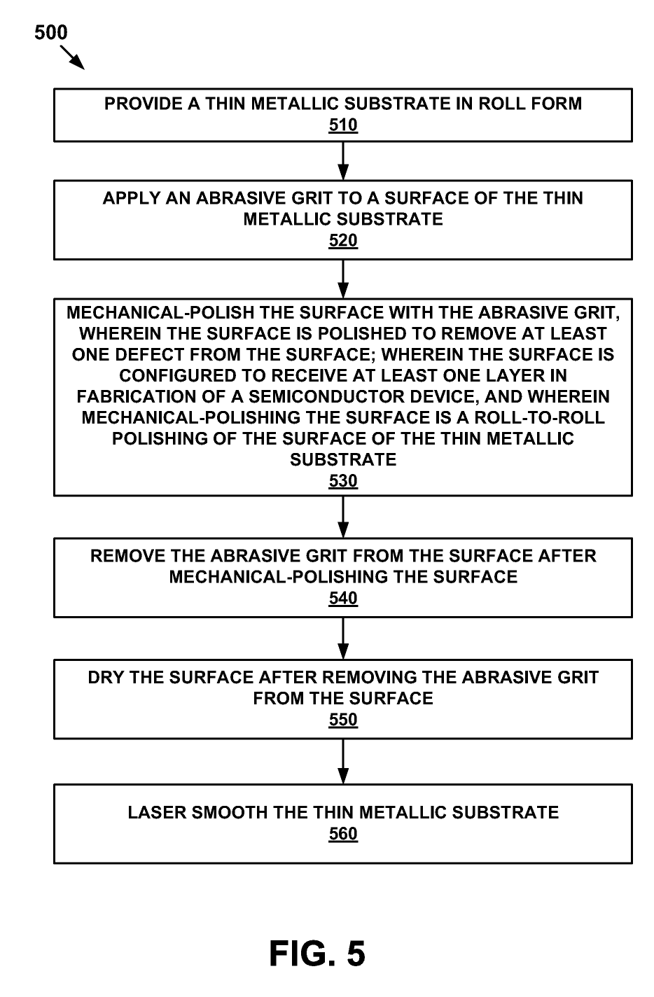

With reference now to FIG. 5, a flow chart illustrates an embodiment of the present invention for a method 500 for roll-to-roll polishing the surface of a thin metallic substrate for a semiconductor device. At 510, a thin metallic substrate is provided in roll form; thickness of the thin metallic substrate is between less than 0.015 inches and greater than about 0.0005 inches. At 520, an abrasive grit is applied to a surface of the thin metallic substrate. The application of the abrasive grit to the surface of the thin metallic substrate may include the application of a polishing compound, which includes the abrasive grit as a constituent, to the surface of the thin metallic substrate. Alternatively, the application of the abrasive grit to the surface of the thin metallic substrate may include the application of a flap brush, to which the abrasive grit is bound, to the surface of the thin metallic substrate. Moreover, the application of the abrasive grit to the surface of the thin metallic substrate may include the combination of both the application of a flap brush, to which the abrasive grit is bound, and the application of a polishing compound, which includes the abrasive grit as a constituent, to the surface of the thin metallic substrate. At 530, a surface of the thin metallic substrate may be mechanical-polished with the abrasive grit, for example, with soft, compliant polishing-surfaces, such that the surface is polished to remove at least one defect from the surface. As used herein, a defect on the surface of the thin metallic substrate is defined as a defect capable of producing a shunt defect in a semiconductor device, or solar cell, that is fabricated incorporating the thin metallic substrate. The surface is configured to receive at least one layer in a fabrication process of a semiconductor device. The mechanical-polishing the surface is a roll-to-roll polishing of the surface of the thin metallic substrate. Also, a semiconductor device fabricated with the method may include a solar cell. In addition, at least one layer of a semiconductor device fabricated with the method may include CIGS. Alternatively, the layer of the semiconductor device may further include a semiconductor material selected from the group consisting of CIGS, CdTe and a-Si, without limitation thereto, as the fabrication of a solar cell from a variety of semiconductor materials is within the spirit and scope of embodiments of the present invention. The mechanical-polishing is performed such that local symmetry of lateral forces ensures that the thin metallic substrate is not subjected to a large shear force. The mechanical-polishing may be performed such that the shear force is no larger than produced by a flap brush applying a pressure of about 10 psi. In addition, the mechanical-polishing may be performed with a flap brush applying a pressure less than about 2 psi. Moreover, the mechanical-polishing is performed such that no shear-induced damage of the thin metallic substrate occurs. The mechanical-polishing is performed such that shear deformation, which in the extreme produces shear-induced damage, is no larger than produced by a flap brush applying a pressure of about 10 psi to said thin metallic substrate having a thickness of between less than 0.015 inches and greater than about 0.0005 inches. At 540, the abrasive grit may be removed from the surface after mechanical-polishing the surface; removing the abrasive grit may further include rinsing the surface to remove the abrasive grit from the surface. Although in an alternative embodiment of the present invention, the abrasive grit is bound to the flap brush, the abrasive grit might be transferred to the thin metallic substrate in the process of mechanical-polishing the thin metallic substrate so that transferred abrasive grit may be removed at 540. At 550, the surface is dried after removing the abrasive grit from the surface. In addition, at 560, the thin metallic substrate may be laser smoothed, as is subsequently described. In embodiments of the present invention, the laser smoothing may be performed, either before, or after mechanical-polishing, both before and after mechanical-polishing, or not at all.

With further reference to FIG. 5, it should be recognized that rough substrate surfaces can result in diode shunt sites that result in loss of output power from the solar cell, for example, as described above in FIGS. 2A and 2B. The roll-to-roll polishing includes mechanically polishing away defects from the surface of the thin metallic substrate using an abrasive grit having a grit size such that the mechanical-polishing is completed in a single mechanical-polishing that occurs on a single pass through the mechanical-polishing module 430 as described above in the discussion of FIG. 4. Alternatively, the method 500 may further include at least a second mechanical-polishing that may be applied to the thin metallic substrate, for example, thin metallic substrate 304, on passing through a second of a plurality of mechanical-polishing modules of a roll-to-roll surface polisher, similar to the mechanical-polishing module 430 of the roll-to-roll surface polisher 400, such that the surface is polished to remove at least one defect from the surface of the thin metallic substrate. Moreover, the roll-to-roll polishing process may include producing a plurality of scratches with an abrasive grit having a grit size such that an average depth of the plurality of scratches is large enough for efficient removal of material from the thin metallic substrate, but a depth of a scratch of the plurality of scratches is small enough as not to create a defect larger than a size that could cause damage to the semiconductor device. The depth of the scratch produced by the grit size may be less than about 5 μm, so as not to create a defect larger than the size that could cause damage to the semiconductor device. The grit size may be less than about 50 μm; alternatively, the grit size may be between about 1 μm and about 10 μm, without limitation thereto. The use of mechanical-polishing facilitates the fabrication of the solar cell by allowing the subsequent deposition of continuous and un-interrupted thin-film layers of solar-cell materials, for example, the absorber layer, on a mechanical-polished thin metallic substrate.

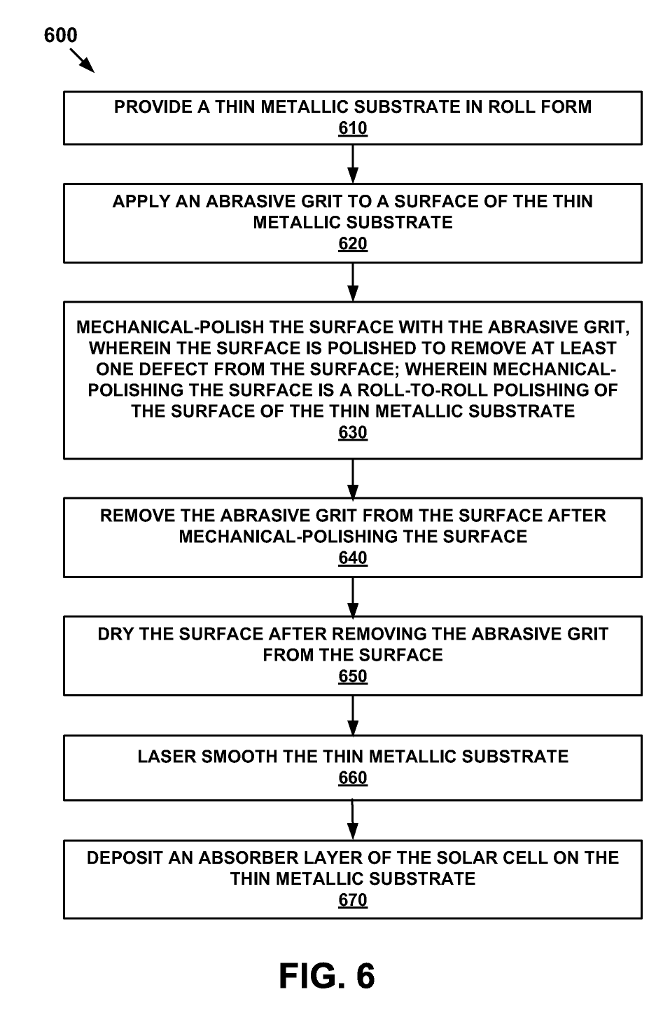

With reference now to FIG. 6, a flow chart illustrates an embodiment of the present invention for a method 600 for fabricating a solar cell. At 610, a thin metallic substrate is provided in roll form; thickness of the thin metallic substrate is between less than 0.015 inches and greater than about 0.0005 inches. At 620, an abrasive grit is applied to a surface of the thin metallic substrate. The application of the abrasive grit to the surface of the thin metallic substrate may include the application of a polishing compound, which includes the abrasive grit as a constituent, to the surface of the thin metallic substrate. Alternatively, the application of the abrasive grit to the surface of the thin metallic substrate may include the application of a flap brush, to which the abrasive grit is bound, to the surface of the thin metallic substrate. Moreover, the application of the abrasive grit to the surface of the thin metallic substrate may include the combination of both the application of a flap brush, to which the abrasive grit is bound, and the application of a polishing compound, which includes the abrasive grit as a constituent, to the surface of the thin metallic substrate. At 630, a surface of the thin metallic substrate is mechanical-polished with the abrasive grit, for example, with soft, compliant polishing-surfaces, such that the surface is polished to remove at least one defect from the surface. As used herein, a defect on the surface of the thin metallic substrate is defined as a defect capable of producing a shunt defect in a solar cell, or semiconductor device, that is fabricated incorporating the thin metallic substrate. The mechanical-polishing the surface is a roll-to-roll polishing of the surface of the thin metallic substrate. The mechanical-polishing is performed such that local symmetry of lateral forces ensures that the thin metallic substrate is not subjected to a large shear force. The mechanical-polishing may be performed such that the shear force is no larger than produced by a flap brush applying a pressure of about 10 psi. Moreover, the mechanical-polishing may be performed with a flap brush applying a pressure less than about 2 psi. Moreover, the mechanical-polishing is performed such that no shear-induced damage of the thin metallic substrate occurs. The mechanical-polishing is performed such that shear deformation, which in the extreme produces shear-induced damage, is no larger than produced by a flap brush applying a pressure of about 10 psi to said thin metallic substrate having a thickness of between less than 0.015 inches and greater than about 0.0005 inches. At 640, the abrasive grit may be removed from the surface after mechanical-polishing the surface; removing the abrasive grit may further include rinsing the surface to remove the abrasive grit from the surface. Although in an alternative embodiment of the present invention, the abrasive grit is bound to the flap brush, the abrasive grit might be transferred to the thin metallic substrate in the process of mechanical-polishing the thin metallic substrate so that transferred abrasive grit may be removed at 640. At 650, the surface is dried after removing the abrasive grit from the surface. In addition, at 660, the thin metallic substrate may be laser smoothed, as is subsequently described. In embodiments of the present invention, the laser smoothing may be performed, either before, or after mechanical-polishing, both before and after mechanical-polishing, or not at all. At 670, an absorber layer is deposited on the thin metallic substrate; the absorber layer may include CIGS. Alternatively, the absorber layer may further include a semiconductor material selected from the group consisting of CIGS, CdTe and a-Si, without limitation thereto, as the fabrication of a solar cell from a variety of semiconductor materials is within the spirit and scope of embodiments of the present invention.

With further reference to FIG. 6, it should be recognized that rough substrate surfaces can result in diode shunt sites that result in loss of output power from the solar cell, for example, as described above in FIGS. 2A and 2B. The roll-to-roll polishing includes mechanically polishing away defects from the surface of the thin metallic substrate using an abrasive grit having a grit size such that the mechanical-polishing is completed in a single mechanical-polishing that occurs on a single pass through the mechanical-polishing module 430 as described above in the discussion of FIG. 4. Alternatively, the method may further include at least a second mechanical-polishing that may occur on passing through a plurality of mechanical-polishing modules of a roll-to-roll surface polisher, similar to the mechanical-polishing module 430 of the roll-to-roll surface polisher 400, wherein the surface is polished to remove at least one defect from the surface. Moreover, the roll-to-roll polishing process may include producing a plurality of scratches with an abrasive grit having a grit size such that an average depth of the plurality of scratches is large enough for efficient removal of material from the thin metallic substrate, but a depth of a scratch of the plurality of scratches is small enough as not to create a defect larger than a size that could cause damage to the semiconductor device. The depth of the scratch produced by the grit size may be less than about 5 μm, so as not to create a defect larger than the size that could cause damage to the solar cell. The use of mechanical-polishing facilitates the fabrication of the solar cell by allowing the subsequent deposition of continuous and un-interrupted thin-film layers of solar-cell materials, for example, the absorber layer, on a mechanical-polished thin metallic substrate.

### Physical Description of Embodiments of the Present Invention for a Solar Cell Having a Laser-Smoothed Thin Metallic Substrate

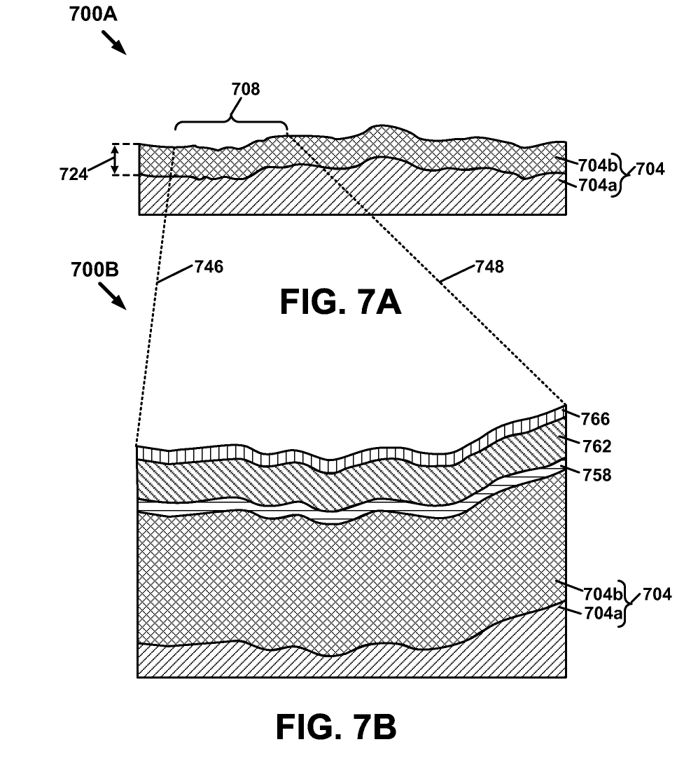

With reference now to FIG. 7A, in accordance with an embodiment of the present invention, a cross-sectional elevation view 700A of a thin metallic substrate 704 after irradiating a surface of the thin metallic substrate 704 with a high-intensity energy source is shown. The thin metallic substrate 704 includes a supporting portion 704a and an altered surface layer 704b. The surface of the thin metallic substrate 704 is smoothed by irradiating the surface of the thin metallic substrate 704 with a high-intensity energy source, in which the surface is smoothed to remove at least one defect from the surface by creating the altered surface layer 704b of the thin metallic substrate 704 on the supporting portion 704a of the thin metallic substrate 704. In one embodiment, the altered surface layer 704b has a thickness 724 of less than about 5 μm; alternatively, the altered surface layer 704b may be less than about 25 μm. Smoothing may be accomplished with a single pass of irradiation from the high-intensity energy source over the surface of the thin metallic substrate 704, or alternatively with a plurality of passes of irradiation from the high-intensity energy source over the surface of the thin metallic substrate 704. For example, two passes of irradiation from the high-intensity energy source may be used: a first, to remove inclusions from the surface, for example, by vaporization of the inclusions; a second, to further smooth the surface, for example, by reflowing vestigial craters at the location of inclusions vaporized in the first pass. Within the spirit and scope of embodiments of the present invention, additional passes beyond two may even be used with further smoothing of the surface topography, although the accrued smoothness may come with diminished returns.

After the thin metallic substrate 704 is smoothed, in accordance with an embodiment of the present invention, the thin metallic substrate 704 is suitable for further fabrication of a semiconductor device including, for example, a solar cell. An absorber layer 762 of the solar cell may be disposed on the altered surface layer 704b, as shown in FIG. 7B; the absorber layer 762 may include a layer of CIGS material. Alternatively, the absorber layer 762 may further include a semiconductor material selected from the group consisting of CIGS, CdTe and a-Si, without limitation thereto, as the fabrication of a solar cell from a variety of semiconductor materials is within the spirit and scope of embodiments of the present invention. The smoothing may include a laser smoothing, wherein the laser smoothing further includes a process selected from a group including a laser ablation process, a laser melting-resolidification process, and a laser-induced, surface-alloying process. Similarly, the high-intensity energy source may include a laser selected from a group including a Q-switched laser, a Q-switched neodymium-doped, yttrium-aluminum-garnet (Nd:YAG) laser, a Q-switched fiber laser, a Q-switched disc laser, a Q-switched slab laser, a carbon-dioxide laser, a pulsed laser, a continuous-wave laser, and a diode laser. As described above in embodiments of the present invention, lasers have been identified as one type of high-intensity energy source, but this does not preclude other high-intensity energy sources outside of lasers that are within the spirit and scope of embodiments of the present invention. In addition, prior to irradiating the surface of the thin metallic substrate 704 with the high-intensity energy source, a surface-treatment layer may be deposited on the thin metallic substrate 704. The deposition process for depositing the surface-treatment layer may be selected from a group including physical vapor deposition (PVD), chemical vapor deposition (CVD), sol-gel deposition, sputtering, sputtering in a reactive atmosphere, cladding, laser cladding, electroplating, and electroless plating.

In accordance with an embodiment of the present invention, a Q-switched Nd:YAG laser may be used having a peak intensity of about 2 megaWatt (MW) during a Q-switched pulse duration of about 40 nanoseconds (ns); otherwise, in non-Q-switched, continuous mode operation, the Nd:YAG laser may an average power of 50 Watts (W). The laser beam delivered at the sample is homogenized by passing it through a beam homogenizer including an optical fiber having a square cross-section and a stepped index of refraction along its length to produce a large square spot of uniform intensity at the thin metallic substrate 704 with a dimension of about 1.5 millimeters (mm) by 1.5 mm. In one embodiment of the present invention, the spot may be rastered across the surface of the sample in a raster pattern with a speed of about 4 meters per second (m/s) using a laser galvanometer scanner to produce an overall rate of laser smoothing of about 100 square centimeters per second (cm²/s).

With further reference to FIG. 7A, in accordance with the embodiment of the present invention, a portion 708 of the thin metallic substrate 704 corresponding to the pit 208 of FIG. 2A is shown after irradiating the surface of the thin metallic substrate 704 with a high-intensity energy source, such as a laser. The altered surface layer 704b of the thin metallic substrate 704 fills in the cavity portion 208d of the pit 208 leaving a gently undulating surface topography suitable for further fabrication of a semiconductor device, such as a solar cell. The other defects: the carbonaceous residue 212, the protrusion 216, the inclusion 220, and the rolling groove 224, have been removed from the surface of the thin metallic substrate 704 having either been ablated from the surface or incorporated into the altered surface layer 704b as alloying constituents, for example, the inclusion 220. The roughness of the surface after irradiating the thin metallic substrate 704 with a laser is substantially less than the peak-to-valley roughness 240, given by distance between the top of the protrusion 216 and the bottom of the rolling groove 224 shown in FIG. 2A, before irradiating the thin metallic substrate 704 with a laser.

With reference now to FIG. 7B, an expanded view 700B of a portion of the cross-sectional elevation view 700A of FIG. 7A is shown as indicated by lines of projection 746 and 748. In accordance with an embodiment of the present invention, a cross-sectional elevation view of a layer structure of a solar cell is shown as it would appear after irradiating the surface of the thin metallic substrate 704 with a high-intensity energy source, such as a laser, and depositing layers to fabricate the solar cell with the layers disposed on the altered surface layer 704b of the thin metallic substrate 704. The solar cell includes the thin metallic substrate 704 with the surface of the thin metallic substrate 704 smoothed by irradiating the surface with a high-intensity energy source, so that the surface is smoothed to remove at least one defect from the surface by creating the altered surface layer 704b and the absorber layer 762 disposed on the altered surface layer 704b of the thin metallic substrate 704. The absorber layer 762 of the solar cell may include CIGS. Alternatively, the absorber layer 762 may further include a semiconductor material selected from the group consisting of CIGS, CdTe and a-Si, without limitation thereto, as the fabrication of a solar cell from a variety of semiconductor materials is within the spirit and scope of embodiments of the present invention. A conductive backing layer 758 may be disposed between the absorber layer 762 and the altered surface layer 704b of the thin metallic substrate 704. On the surface of the absorber layer 762, a TCO layer 766 is disposed. As shown in the expanded view of FIG. 7B, the location corresponding to the cavity portion 208d of the pit 208 has a gently undulating surface topography. Therefore, the shunt defect associated with the defect, pit 208, shown in FIG. 2A, is absent, as well as other shunt defects, so that the number of shunt defects and density of shunt defects is reduced. In addition, the altered surface layer 704b has a thickness of less than about 5 μm sufficient to remove at least one defect within 5 μm of the top of the original surface of the thin metallic substrate 704; alternatively, the altered surface layer 704b may have a thickness of less than about 25 μm depending on the power delivered to the surface of the thin metallic substrate 704 by the high-intensity energy source. Moreover, after smoothing the surface of the thin metallic substrate 704, the altered surface layer 704b has a gently undulating topography. The smoothing may include a laser smoothing which may also include a process selected from a group including a laser ablation process, a laser melting-resolidification process, and a laser-induced, surface-alloying process. In addition, the high-intensity energy source may include a laser selected from a group including a Q-switched laser, a Q-switched Nd:YAG laser, a Q-switched fiber laser, a Q-switched disc laser, a Q-switched slab laser, carbon-dioxide laser, a pulsed laser, a continuous-wave laser, and a diode laser.

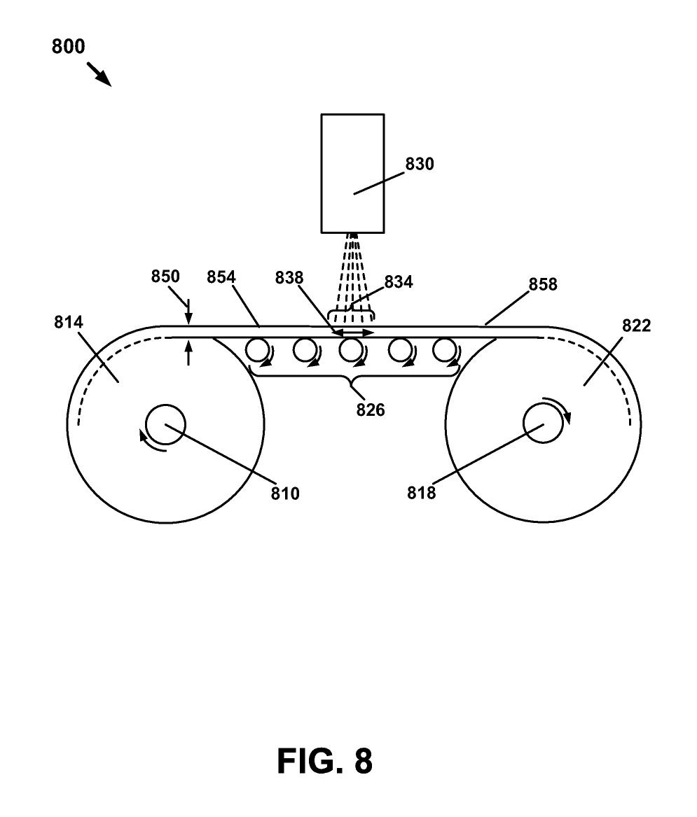

With reference now to FIG. 8, in accordance with an embodiment of the present invention, an elevation view of a roll-to-roll surface smoother 800 for smoothing the surface of thin metallic substrate in roll form is shown. The thin metallic substrate is provided to roll-to-roll surface smoother 800 in roll form from a roll of material 814. The roll-to-roll surface smoother 800 includes an unwinding spool 810 upon which the roll of material 814 including the thin metallic substrate in roll form is mounted. As shown, a portion of the roll of material 814 is unwound and passes over a series of idler rollers 826, shown as five small circles in the center of FIG. 8, which provide a roller-platform upon which the unwound portion of the roll of material 814 may be transported. The unwound portion of the roll of material 814 passes to the right and is taken up on a take-up spool 818 upon which it is rewound as a smoothed roll of material 822 after the thin metallic substrate has been smoothed. The arrows adjacent to the idler rollers 826, the unwinding spool 810, and the take-up spool 818 indicate that these are configured as rotating components of the roll-to-roll surface smoother 800; the idler rollers 826, the unwinding spool 810, and the take-up spool 818 are shown rotating in clockwise direction, as indicated by the arrow-heads on the respective arrows adjacent to these components, to transport the unwound portion of the roll of material 814 from the unwinding spool 810 on the left to the take-up spool 818 on the right.

With further reference to FIG. 8, in accordance with an embodiment of the present invention, the roll of material 814 provides the thin metallic substrate as a sheet having a width (not shown), as great as about 1 m, and a thickness 850, as great as about 125 μm. As provided the untreated surface 854 of the roll of material 814 passes under a surface treatment station on the way to the take-up spool 818. The surface treatment station includes a high-intensity energy source 830 from which a high-intensity energy beam 834 emanates to irradiate the untreated surface 854 of the roll of material 814 to smooth the untreated surface 854, such as shown in FIGS. 2A and 2B, producing a smoothed surface 858, such as shown in FIGS. 3A and 3B, on the thin metallic substrate; in this way, the surface is smoothed to remove at least one defect from the surface by creating the altered surface layer 704b. The high-intensity energy beam 834 may have a range 838 over which the high-intensity energy beam 834 irradiates the surface of the unwound portion of the roll of material 814. The range 838 may be provided by homogenizing the beam to produce a wide spot with a beam homogenizer, or by rastering a focused spot back and forth along the direction of transport as indicated by the double-headed arrow corresponding to the range 838. As the thin metallic substrate also has a width, the high-intensity energy beam 834 may be rastered in the width direction, perpendicular to the direction of transport (not shown), to smooth the full surface of the thin metallic substrate. As shown in FIG. 8, the untreated surface 854 is the outer surface of the roll of material 814. Alternatively, by disposing a treatment station on the opposite, or bottom, side of the unwound portion from that shown, the inner surface of the roll of material 814 may be smoothed (not shown).

With further reference to FIG. 8, in accordance with an embodiment of the present invention, after the surface has been smoothed, the altered surface layer is configured to receive at least one layer in a fabrication process of a semiconductor device, for example, as described above in FIG. 3B. In accordance with an embodiment of the present invention, the thin metallic substrate may be selected from a group including a thin metallic substrate and a thin metallized substrate, for example, a thin metallized non-metallic substrate including a flexible, non-conductive substrate, such as a polymer substrate, with a sputtered metallic layer. In addition, the semiconductor device may include a solar cell having absorber layer 362 made of, for example, CIGS material. Alternatively, the absorber layer may further include a semiconductor material selected from the group consisting of CIGS, CdTe and a-Si, without limitation thereto, as the fabrication of a solar cell from a variety of semiconductor materials is within the spirit and scope of embodiments of the present invention. In accordance with an embodiment of the present invention, the high-intensity energy source may include a laser selected from a group consisting of a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser. Moreover, smoothing may include a laser smoothing including a process selected from a group including a laser ablation process, a laser melting-resolidification process, and a laser-induced, surface-alloying process.

With further reference to FIG. 8 in conjunction with FIG. 7B, in accordance with embodiments of the present invention, the roll-to-roll surface smoother 800 may be used in fabricating a solar cell. The solar cell may include a thin metallic substrate 704, a surface of the thin metallic substrate 704 smoothed by irradiating the surface with a high-intensity energy source 830, wherein the surface is smoothed to remove at least one defect from the surface by creating an altered surface layer 704b; and an absorber layer 762 disposed on the surface of the thin metallic substrate 704. The absorber layer 762 of the solar cell may further include CIGS. Alternatively, the absorber layer may further include a semiconductor material selected from the group consisting of CIGS, CdTe and a-Si, without limitation thereto, as the fabrication of a solar cell from a variety of semiconductor materials is within the spirit and scope of embodiments of the present invention. In further embodiments of the present invention, the thin metallic substrate 704 of the solar cell may be selected from a group consisting of a thin metallic substrate and a thin metallized substrate. Moreover, the substrate 704 may have a width of about 1 m and a thickness of less than about 125 μm. In an embodiment of the present invention, the altered surface layer 704b of the solar cell has a thickness of less than about 25 μm.

### Description of Embodiments of the Present Invention for a Method of Laser-Smoothing a Thin Metallic Substrate for a Solar Cell

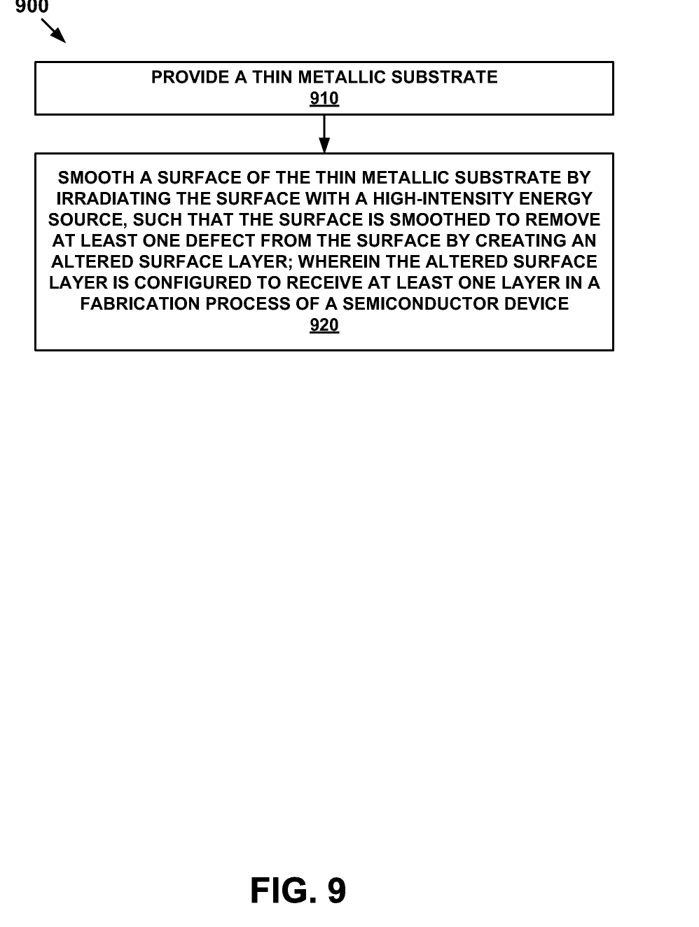

With reference now to FIG. 9, a flow chart illustrates an embodiment of the present invention for a method 900 for smoothing the surface of a thin metallic substrate. At 910, a thin metallic substrate is provided. At 920, a surface of the thin metallic substrate is smoothed by irradiating the surface with a high-intensity energy source, such that the surface is smoothed to remove at least one defect from the surface by creating an altered surface layer, in which the altered surface layer is configured to receive at least one layer in a fabrication process of a semiconductor device. In one embodiment, the altered surface layer produced by the method has a thickness of less than about 5 μm; alternatively, the altered surface layer may have a thickness of less than about 25 μm depending on the power delivered to the surface by the high-intensity energy source. Also, a semiconductor device fabricated with the method may include a solar cell. In addition, at least one layer of a semiconductor device fabricated with the method may include CIGS. Alternatively, the layer of the semiconductor device may further include a semiconductor material selected from the group consisting of CIGS, CdTe and a-Si, without limitation thereto, as the fabrication of a solar cell from a variety of semiconductor materials is within the spirit and scope of embodiments of the present invention.

With further reference to FIG. 9, it should be recognized that rough substrate surfaces can result in diode shunt sites that result in loss of output power from the solar cell, for example, as described above in FIGS. 2A and 2B. Laser smoothing by surface melting locally smoothes the surface by melting and reflowing the surface features without fully penetrating the thin metallic substrate with the laser melt zone. Therefore, the smoothing includes a laser smoothing. The use of laser smoothing facilitates the fabrication of the solar cell by allowing the subsequent deposition of continuous and un-interrupted thin-film layers of solar-cell materials, for example, the absorber layer, on a smoothed thin metallic substrate. In an example laser-smoothing process, the laser preferentially heats regions of the surface having lesser heat capacity than the base portion of the thin metallic substrate, for example, regions with the topography of a protrusion or pit. In addition, such features can be removed by laser smoothing based on laser ablation. Therefore, the laser smoothing may also include a process selected from a group including a laser ablation process, a laser melting-resolidification process, and a laser-induced, surface-alloying process.

In accordance with an embodiment of the present invention, the latter process, laser-induced, surface-alloying, can be accomplished by a variety of methods, including without limitation: applying a material to the surface of the thin metallic substrate before or during the laser-smoothing process to form a thin-film barrier layer, for example, chromium, Cr, which blocks the out-diffusion of impurities, e.g. iron, Fe, or nickel, Ni, from the thin metallic substrate that may have a deleterious effect on solar-cell performance; or, exposing the surface to reactive gases such as nitrogen or oxygen during the laser-smoothing process to form a nitrided, or oxidized, thin-film layer, for example, a thin-film, surface nitride or oxide layer. In the alternative to exposing the surface to a reactive gas, the surface may be shrouded in an envelope of inert gas, for example, argon, Ar, during the laser-smoothing process to maintain surface cleanliness. Moreover, the application of material to the surface of the thin metallic substrate, before or during the laser-smoothing process, may also include depositing a surface-treatment layer on the thin metallic substrate. Thus, in accordance with an embodiment of the present invention, depositing a surface-treatment layer may also include a deposition process selected from a group including physical vapor deposition (PVD), chemical vapor deposition (CVD), sol-gel deposition, sputtering, sputtering in a reactive atmosphere, cladding, laser cladding, electroplating, and electroless plating. Also, in the case of laser cladding, the cladding material may be provided from a variety of sources, including without limitation: powder, wire, liquid, as well as others within the scope and spirit of embodiments of the present invention.

With further reference to FIG. 9, in accordance with an embodiment of the present invention, various laser scanning techniques can be employed to deliver energy from the laser to the surface of the thin metallic substrate. For example, in an embodiment of the present invention, a laser galvanometer scanner may be used to scan a laser beam across the surface of the thin metallic substrate; or alternatively, a linear laser source may be used to irradiate a line, rather than a spot, on the surface of the thin metallic substrate. Moreover, the high-intensity energy source may also include a laser selected from a group including a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser, as embodiments within the spirit and scope of embodiments of the present invention.

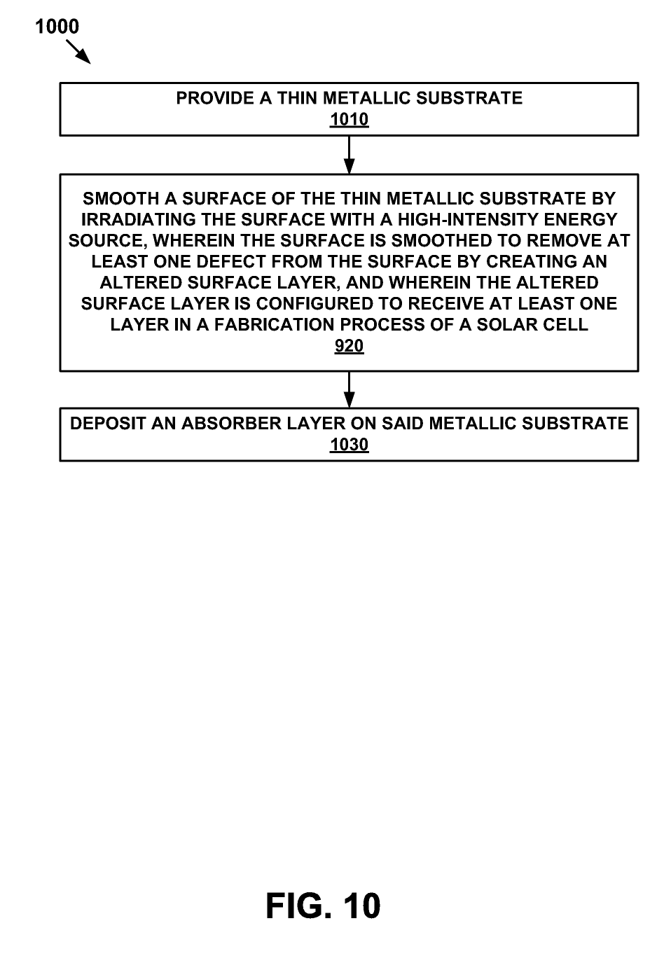

With reference now to FIG. 10, a flow chart illustrates an embodiment of the present invention for a method 1000 for fabricating a solar cell. At 1010, a thin metallic substrate is provided. At 1020, a surface of the thin metallic substrate is smoothed by irradiating the surface with a high-intensity energy source, wherein the surface is smoothed to remove at least one defect from the surface by creating an altered surface layer, and wherein the altered surface layer is configured to receive at least one layer in a fabrication process of a solar cell. At 1030, an absorber layer is deposited on the thin metallic substrate. In one embodiment, the altered surface layer produced by the method has a thickness of less than about 5 μm; alternatively, the altered surface layer may have a thickness of less than about 25 μm depending on the power delivered to the surface by the high-intensity energy source. In an embodiment of the present invention, the absorber layer fabricated with the method includes CIGS. Alternatively, the absorber layer may further include a semiconductor material selected from the group consisting of CIGS, CdTe and a-Si, without limitation thereto, as the fabrication of a solar cell from a variety of semiconductor materials is within the spirit and scope of embodiments of the present invention. With further reference to FIG. 10, in the embodiment of the present invention for the method 1000, the smoothing further includes a laser smoothing. The laser smoothing further includes a process selected from a group including a laser ablation process, a laser melting-resolidification process, and a laser-induced, surface-alloying process. In addition, the high-intensity energy source of the method may also include a laser selected from a group including a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser, as embodiments within the spirit and scope of embodiments of the present invention.

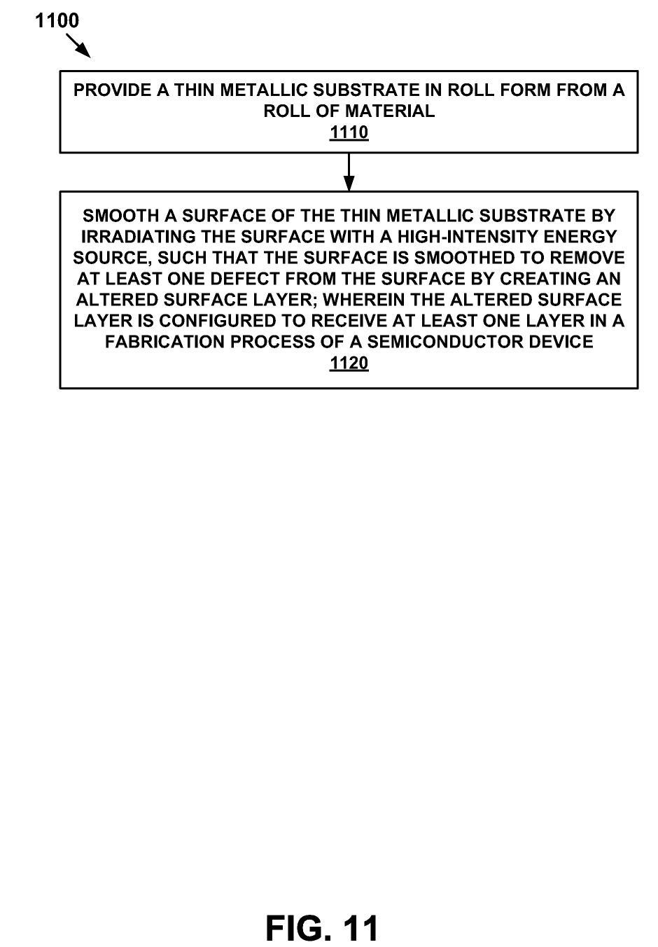

With reference now to FIG. 11, a flow chart illustrates an embodiment of the present invention for a method 1100 for roll-to-roll smoothing the surface of a roll of material. At 1110, a thin metallic substrate in roll form from a roll of material is provided. At 1120, a surface of the roll of material is smoothed by irradiating the surface with a high-intensity energy source, such that the surface is smoothed to remove at least one defect from the surface by creating an altered surface layer, in which the altered surface layer is configured to receive at least one layer in a fabrication process of a semiconductor device. In an embodiment of the present invention, the thin metallic substrate is selected from a group including a thin metallic substrate and a thin metallized substrate, for example, a thin metallized non-metallic substrate including a flexible, non-conductive substrate, such as a polymer substrate, with a sputtered metallic layer. In one embodiment, the altered surface layer produced by the method has a thickness of less than about 5 μm; alternatively, the altered surface layer may have a thickness of less than about 25 μm depending on the power delivered to the surface by the high-intensity energy source. Also, a semiconductor device fabricated with the method may include a solar cell. In addition, at least one layer of a semiconductor device fabricated with the method may include CIGS. Moreover, the layer of the semiconductor device may further include a semiconductor material selected from the group consisting of CIGS, CdTe and a-Si, without limitation thereto, as the fabrication of a solar cell from a variety of semiconductor materials is within the spirit and scope of embodiments of the present invention.

With further reference to FIG. 11, it should be recognized that rough substrate surfaces can result in diode shunt sites that result in loss of output power from the solar cell, for example, as described above in FIGS. 2A and 2B. Laser smoothing by surface melting locally smoothes the surface by melting and reflowing the surface features without fully penetrating the thin metallic substrate with the laser melt zone. Therefore, the smoothing includes a laser smoothing. The use of laser smoothing facilitates the fabrication of the solar cell by allowing the subsequent deposition of continuous and un-interrupted thin-film layers of solar-cell materials, for example, the absorber layer, on a smoothed thin metallic substrate. In an example laser-smoothing process, the laser preferentially heats regions of the surface having lesser heat capacity than the base portion of the thin metallic substrate, for example, regions with the topography of a protrusion or pit. In addition, such features can be removed by laser smoothing based on laser ablation. Therefore, the laser smoothing may also include a process selected from a group including a laser ablation process, a laser melting-resolidification process, and a laser-induced, surface-alloying process.

In accordance with an embodiment of the present invention, the latter process, laser-induced, surface-alloying, can be accomplished by a variety of methods, including without limitation: applying a material to the surface of the thin metallic substrate before or during the laser-smoothing process to form a thin-film barrier layer, for example, chromium, Cr, which blocks the out-diffusion of impurities, e.g. iron, Fe, or nickel, Ni, from the thin metallic substrate that may have a deleterious effect on solar-cell performance; or, exposing the surface to reactive gases such as nitrogen or oxygen during the laser-smoothing process to form a nitrided, or oxidized, thin-film layer, for example, a thin-film, surface nitride or oxide layer. In the alternative to exposing the surface to a reactive gas, the surface may be shrouded in an envelope of inert gas, for example, argon, Ar, during the laser-smoothing process to maintain surface cleanliness. Moreover, the application of material to the surface of the thin metallic substrate before or during the laser-smoothing process may also include depositing a surface-treatment layer on the thin metallic substrate. Thus, in accordance with an embodiment of the present invention, depositing a surface-treatment layer may also include a deposition process selected from a group including physical vapor deposition (PVD), chemical vapor deposition (CVD), sol-gel deposition, sputtering, sputtering in a reactive atmosphere, cladding, laser cladding, electroplating, and electroless plating. Also, in the case of laser cladding, the cladding material may be provided from a variety of sources, including without limitation: powder, wire, liquid, as well as others within the scope and spirit of embodiments of the present invention.

With further reference to FIG. 11, in accordance with an embodiment of the present invention, various laser scanning techniques can be employed to deliver energy from the laser to the surface of the thin metallic substrate. For example, in an embodiment of the present invention, a laser galvanometer scanner may be used to scan a laser beam across the surface of the thin metallic substrate; or alternatively, a linear laser source may be used to irradiate a line, rather than a spot, on the surface of the thin metallic substrate. Moreover, the high-intensity energy source may also include a laser selected from a group including a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser, as embodiments within the spirit and scope of embodiments of the present invention.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments described herein were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A method for fabricating a solar cell, said method comprising:
providing a thin metallic substrate in roll form;
applying an abrasive grit to a surface of said thin metallic substrate;
mechanical-polishing said surface with said abrasive grit wherein said surface is polished to remove at least one defect from said surface; and
depositing an absorber layer of said solar cell on said thin metallic substrate;
wherein said mechanical-polishing said surface is a roll-to-roll polishing of said surface of said thin metallic substrate.

2. The method recited in claim 1, wherein said applying said abrasive grit to said surface of said thin metallic substrate further comprises applying a polishing compound to said surface of said thin metallic substrate, said polishing compound including said abrasive grit as a constituent,

3. The method recited in claim 1, wherein said applying said abrasive grit to said surface of said thin metallic substrate further comprises applying a flap brush to said surface of said thin metallic substrate, said abrasive grit bound to said flap brush.

4. The method recited in claim 1, wherein said absorber layer further comprises a semiconductor material selected from the group consisting of copper indium gallium diselenide (CIGS), cadmium telluride (CdTe) and amorphous silicon (a-Si).

5. The method recited in claim 1, said method further comprising:
using an abrasive grit having a grit size such that said mechanical-polishing is completed in a single mechanical-polishing.

6. The method recited in claim 1, said method further comprising at least a second mechanical-polishing wherein said surface is polished to remove at least one defect from said surface.

7. The method recited in claim 1, said method further comprising:
producing a plurality of scratches with an abrasive grit having a grit size such that an average depth of said plurality of scratches is large enough for efficient removal of material from said thin metallic substrate, but a depth of a scratch of said plurality of scratches is small enough as not to create a defect larger than a size that could cause damage to said solar cell.

8. The method recited in claim 7, wherein said depth of said scratch produced by said grit size is less than about 5 μm.

9. The method recited in claim 7, wherein said grit size is less than about 50 μm.

10. The method recited in claim 7, wherein said grit size is between about 1 μm and about 10 μm.

11. The method recited in claim 1, wherein a thickness of said thin metallic substrate is between less than 0.015 inches and greater than about 0.0005 inches.

12. The method recited in claim 1, wherein said mechanical-polishing is performed such that local symmetry of lateral forces ensures that said thin metallic substrate is not subjected to a large shear force.

13. The method recited in claim 1, wherein said mechanical-polishing is performed such that a shear force is no larger than produced by a flap brush applying a pressure of about 10 psi.

14. The method recited in claim 1, wherein said mechanical-polishing is performed with a flap brush applying a pressure less than about 2 psi.

15. The method recited in claim 1, wherein said mechanical-polishing is performed such that no shear-induced damage of the thin metallic substrate occurs.

16. The method recited in claim 1, wherein said mechanical-polishing is performed such that a shear deformation is no larger than produced by a flap brush applying a pressure of about 10 psi to said thin metallic substrate having a thickness of between less than 0.015 inches and greater than about 0.0005 inches.

17. The method recited in claim 1, said method further comprising:
laser smoothing said thin metallic substrate.

18. A method for roll-to-roll polishing the surface of a thin metallic substrate for a semiconductor device, said method comprising:
providing said thin metallic substrate in roll form;
applying an abrasive grit to a surface of said thin metallic substrate; and
mechanical-polishing said surface with said abrasive grit wherein said surface is polished to remove at least one defect from said surface;
wherein said surface is configured to receive at least one layer in a fabrication process of said semiconductor device; and
wherein said mechanical-polishing said surface is a roll-to-roll polishing of said surface of said thin metallic substrate.

19. The method recited in claim 18, wherein said applying said abrasive grit to said surface of said thin metallic substrate further comprises applying a polishing compound to said surface of said thin metallic substrate, said polishing compound including said abrasive grit as a constituent,

20. The method recited in claim 18, wherein said applying said abrasive grit to said surface of said thin metallic substrate further comprises applying a flap brush to said surface of said thin metallic substrate, said abrasive grit bound to said flap brush.

21. The method recited in claim 18, wherein said semiconductor device comprises a solar cell.

22. The method recited in claim 18, said method further comprising:
using an abrasive grit having a grit size such that said mechanical-polishing is completed in a single mechanical-polishing.

23. The method recited in claim 18, said method further comprising at least a second mechanical-polishing wherein said surface is polished to remove at least one defect from said surface.

24. The method recited in claim 18, said method further comprising:
producing a plurality of scratches with an abrasive grit having a grit size such that an average depth of said plurality of scratches is large enough for efficient removal of material from said thin metallic substrate, but a depth of a scratch of said plurality of scratches is small enough as not to create a defect larger than a size that could cause damage to said semiconductor device.

25. The method recited in claim 24, wherein said depth of said scratch produced by said grit size is less than about 5 μm

26. The method recited in claim 24, wherein said grit size is less than about 50 μm.

27. The method recited in claim 24, wherein said grit size is between about 1 μm and about 10 μm.

28. The method recited in claim 24, wherein said semiconductor device comprises a solar cell.

29. The method recited in claim 18, wherein said at least one layer comprises a semiconductor material selected from the group consisting of copper indium gallium diselenide (CIGS), cadmium telluride (CdTe) and amorphous silicon (a-Si).

30. The method recited in claim 18, wherein a thickness of said thin metallic substrate is between less than 0.015 inches and greater than about 0.0005 inches.

31. The method recited in claim 18, wherein said mechanical-polishing is performed such that local symmetry of lateral forces ensures that said thin metallic substrate is not subjected to a large shear force.

32. The method recited in claim 18, wherein said mechanical-polishing is performed such that a shear force is no larger than produced by a flap brush applying a pressure of about 10 psi.

33. The method recited in claim 18, wherein said mechanical-polishing is performed with a flap brush applying a pressure less than about 2 psi.

34. The method recited in claim 18, wherein said mechanical-polishing is performed such that no shear-induced damage of said thin metallic substrate occurs.

35. The method recited in claim 18, wherein said mechanical-polishing is performed such that a shear deformation is no larger than produced by a flap brush applying a pressure of about 10 psi to said thin metallic substrate having a thickness of between less than 0.015 inches and greater than about 0.0005 inches.

36. The method recited in claim 18, said method further comprising:
removing said abrasive grit from said surface after mechanical-polishing said surface.

37. The method recited in claim 36, wherein said removing said abrasive grit further comprises:
rinsing said surface to remove said abrasive grit from said surface.

38. The method recited in claim 36, said method further comprising:
drying said surface after removing said abrasive grit from said surface.

39. The method recited in claim 18, said method further comprising:
laser smoothing said thin metallic substrate.

40. A solar cell, comprising:
a thin metallic substrate, a surface of said thin metallic substrate mechanical-polished with an abrasive grit applied to said surface in a roll-to-roll process, said surface having a plurality of scratches such that an average depth of said plurality of scratches is sufficient to remove at least one defect from said surface; and
an absorber layer of said solar cell disposed on said surface of said thin metallic substrate;
wherein a thickness of said thin metallic substrate is between less than 0.015 inches and greater than about 0.0005 inches.

41. The solar cell recited in claim 40, wherein said abrasive grit applied to said surface of said thin metallic substrate further comprises a polishing compound applied to said surface of said thin metallic substrate, said polishing compound including said abrasive grit as a constituent,

42. The solar cell recited in claim 40, wherein said abrasive grit applied to said surface of said thin metallic substrate further comprises a flap brush applied to said surface of said thin metallic substrate, said abrasive grit bound to said flap brush.

43. The solar cell recited in claim 40, wherein said absorber layer further comprises a semiconductor material selected from the group consisting of copper indium gallium diselenide (CIGS), cadmium telluride (CdTe) and amorphous silicon (a-Si).

44. The solar cell recited in claim 40, wherein said thin metallic substrate comprises a material composed of stainless steel.

45. The solar cell recited in claim 40, wherein a scratch in said surface of said thin metallic substrate is small enough as not to create a defect larger than a size that could cause damage to said solar cell.

46. The solar cell recited in claim 40, wherein said depth of said scratch produced by said grit size is less than about 5 μm.

47. The solar cell recited in claim 40, wherein a surface of said thin metallic substrate is laser smoothed, having an altered surface layer.
